(19) United States
(12) Patent Application Publication
(10) Pub. No.: US 2026/0153317 A1
(43) Pub. Date: Jun. 4, 2026

(54) BLAST, FRAGMENT AND BATTERY FIRE MITIGATION APPARATUS

(71) Applicant: Disablement Technologies and Consulting LLC, Fredericksburg, VA (US)

(72) Inventor: Ian B. VABNICK, Fredericksburg, VA (US)

(21) Appl. No.: 18/971,962

(22) Filed: Dec. 6, 2024

Related U.S. Application Data
(60) Provisional application No. 63/606,860, filed on Dec. 6, 2023.
(60) Provisional application No. 63/566,689, filed on Mar. 18, 2024.
(60) Provisional application No. 63/636,823, filed on Apr. 21, 2024.

(51) Int. Cl. F42D 5/05; A62C 3/08; A62C 3/16; A62C 8/06; H05K 9/00

(52) U.S. Cl. CPC F42D 5/05; A62C 3/08; A62C 3/16; A62C 8/06; H05K 9/0081

(57) ABSTRACT

Provided herein is a blast and fragment mitigating apparatus (BAFMA), including in a blanket configuration, and related methods useful for containing a hazardous device or cargo. The BAFMA can be capsule shaped and composed of two identical subassemblies that are operably connected to form a volume for containing the device or cargo. The center of some systems may comprise a bladder filled with a fluid body, which may be a dilatant or adsorbent material. There are layers with different material physical and chemical properties that surround the inner volume. The BAFMA can contain hazardous contents on aircraft, intermodal transportation systems, and can be used in bomb disposal operations. Further applications include BAFMA as a battery blanket useful for retarding and suppressing battery fires, including lithium-ion battery fires.

### CROSS REFERENCE TO RELATED APPLICATIONS

This application claims benefit of priority to U.S. Provisional App. Nos. 63/606,860 filed Dec. 6, 2023, 63/566,689 filed Mar. 18, 2024, and 63/636,823 filed Apr. 21, 2024, each of which are specifically incorporated by reference to the extent not inconsistent herewith.

### BACKGROUND

Provided herein is a Blast and Fragment Mitigation Apparatus (BAFMA), including in a blanket configuration, and related methods of containing a hazardous device, including attenuation of one or more hazardous physical parameters associated with a hazardous device initiation, such as explosion of an explosive device or a thermal runaway event of a battery.

The BAFMA is a versatile, scalable, and portable hazardous device or hazardous cargo containment system. A hazardous device can be an improvised explosive device (IED), a commercial explosive firing train or components thereof, or military ordnance; these terms will be used interchangeably herein. IEDs and modified ordnance are often used by terrorists. The hazardous device can also be a commercially available device, such as a battery, including a rechargeable battery. Hazardous cargo can be bulk high explosives, detonators, propellants, pyrotechnics, chemicals, fuels, or energy storage devices such as lithium-ion batteries. The BAFMA protects against explosive blast, thermal runaway, combustion byproducts, and fragmentation produced by initiation of a hazardous device or hazardous cargo. The hazardous device or hazardous cargo may generically be referred to herein as the contents. The BAFMA mitigates hazardous cargo that may react or decompose producing toxic gaseous byproducts and contamination. Often reactions are exothermal and if there is a runaway reaction the result can be explosive and release large amounts of heat and gas. There is an increased demand of rechargeable and disposable batteries that are dense energy storage power sources; are used in personal electronic devices (PEDs), power tools, bicycles, and automobiles. A popular chemical battery is the lithium-ion battery. They may fail due to overcharging, manufacturing flaws, flooding, or mechanical and electrical damage due to mishandling. Thermal build up inside of a lithium-ion battery or chemicals may cause rapid decomposition, ignition followed by a runaway thermal reaction.

The BAFMA is a multi-layer system and, depending on the nature of the hazard, different layers may have different thicknesses, volumes, and material composition. Each layer has one or more functions: attenuate high explosive shocks, decelerate and trap high velocity fragments, absorb heat, and filter toxic vapors. The heart of the BAFMA system is the centrally located bladder(s) that are filled with a Newtonian fluid or a dilatant fluid/slurry forming a fluid body. The fluid body has high heat capacity, can be nonhomogeneous, has a high auto-ignition temperature, and is viscous or viscoelastic under dynamic conditions. If there is an ignition, the bladder will burst and the fluid body will flow around the hazardous device or cargo and deprive a chemical or a material of oxygen from air by surrounding it and preventing oxygen from migrating through. The liquid is adsorbent and will coat a chemical or item which means vapors and gaseous byproducts cannot readily pass through it. The liquid also will slow and deform projectiles such as bomb fragments.

Terrorists use improvised explosive devices (IEDs) to target population centers, social/political events, places of National interest, critical infrastructure, and intermodal transportation systems to disrupt commerce. An attack on an aircraft or at an airport is a major concern. The BAFMA effectively reduces the peak blast overpressure, shock impulse, and fragmentation hazard of IEDs on an aircraft. There are other reasons for a BAFMA on an aircraft such as when a passenger's PED has a battery fire, including a lithium-ion battery fire. The related chemistries that make such battery fires of concern, including in a range of applications, is further expanded upon later.

If an IED were to function while in flight or on the ground, current mitigation techniques are designed to cause localized structural failure in such a way that the aircraft does not catastrophically break apart and critical systems are not damaged. The current response procedure is to improvise bomb containment using seat cushions, passenger personal garments and other fabrics. The materials are stacked and then wetted. This technique has limited blast reduction and is not effective at fragment capture. The containment structure is entirely dependent on what is available, and the experience of the flight crew to properly assemble the protective works. In testing, this emergency improvised containment was shown to direct explosive pressure laterally and cause an aircraft structural breach to rapidly relieve the blast overpressure. If not relieved, this pressure will cause the aircraft to blow apart. The BAFMA minimizes the explosive effects of an IED positioned at a least risk bomb location (LRBL).

Hazardous device removal from the aircraft is necessary via remote and/or semi-remote means by bomb technicians. The technology described herein is designed to facilitate rapid and safe removal of an IED, including by bomb technicians, which eliminates the need for disrupters and high explosive charges on an aircraft to controllably dispose of the IED. Currently, bomb neutralizing tools will cause significant damage. After a bomb is removed from an aircraft in a containment system, it needs to be neutralized. The bomb technician needs to access the bomb and current LRBL blast containment system designs do not take this into consideration. The BAFMA is configured so that a robot or bomb technician can remotely or semi-remotely expose the bomb for disruption.

In addition to aircraft, other critical infrastructure sites may not be able to withstand a detonation. Bomb squads, military explosive ordnance disposal units and protective security services such as US Secret Service (USSS) need compact light-weight containment systems to transport hazardous devices or to create protective works. The latter is used to prevent damage to nearby property and protect persons from serious harm or death.

Many blast and ballistic containment systems are described in the art. Their structure can be a single material structure or made of composite materials or layers to create barriers to absorb shock energy and slow fragments or bullets. They can also have specific shapes and structure to deflect or disperse shocks and projectiles. Few are lightweight and portable. Many bomb containment systems cannot be stored in a cabinet such as those on passenger aircraft. And those that can have limited over-pressure and thermal protection.

The most commonly used bomb transport and containment system is known as a single vent system that is barrel shaped. Generally, they are vessels made of steel. The idea is that the steel armor stops fragments and the blast wave is directed upwards rather than radially. This is because air is readily compressible, and pressure drops with the inverse square of the distance from a spherical charge. Tightly wrapped steel wire has been shaped into blast containing structures and blast mats. The small spaces allow explosive gases to vent in a controlled manner. Radial tire rubber has also been incorporated in blast containment trash receptacles and bomb containment vessels. Total containment vessels are massive hollow steel balls and have a hermetically sealed locking multi-pin door. In most designs of blast and fragmentation containment vessels, the hazardous device is suspended in the inner volume and not touching its sides. Those containment systems can weigh between 5,000 lbs. and 15,000 lbs.

One containment system uses sealed flexible rubber bladders that are filled with water (U.S. Pat. No. 4,836,079). The bladders can be shaped for different purposes. In one embodiment, the bladder is placed on top of a bomb. In another embodiment, a wall of stacked bladders forms a rectangular structure that surrounds the bomb. The bomb is centered and is not in contact with the water-filled bladders. This configuration is often referred to as protective works. That system does not contain an aramid fiber layer or rigid structural elements. The main function of that system was to mitigate the bomb blast and not fragments. Furthermore, the system is not transportable.

Portable systems to transport small hazardous devices include fragmentation bags and, as their name implies, they mainly stop or slow bomb fragments. Some are made from rubber that has fibers interweaved in it or rubber with steel radial material. Explosives storage vaults and magazines are steel walled and may contain an inner wall of plywood. There are also bags made of aramid fibers such as Kevlar®. Cargo bags such as the FLY-BAG and FLY-BAG2 are double layers of ballistic aramid fibers and a zipper lock (WO 2016/050346). That system has been considered for the LRBL and cargo hull of aircraft. It will do a good job of stopping fragments; however, it will provide limited blast overpressure protection. The system is designed to vent gases, however, reflected shocks due to confinement limit the potential of the system. Aramid fibers are fire resistant, and the that system describes adding a thin coating of silicone, for example, to further increase its thermal resistance, however, that coating may restrict the escape of gas products. The sealed zippered bag is challenging for bomb technicians to use robotics or to use semi-remote methods to open it. They are forced to manually unzip the bag and remove the IED. The FLY-BAG has limited effectiveness to protect against a thermal runaway event due to a battery failure, such as lithium battery failure. It does not have fire suppression elements or toxic vapor neutralization.

To address a fire, blast, and fragmentation, an apparatus is comprised of inflating a plurality of flexible ballistic cubes (US Pat. Pub. 2011/0168004). The proposed gas that fills the interlocking cubes is released by a cylinder of halon; a fire suppressant used on aircraft. There is an inner liner of an airtight material and an outer aramid liner for ballistic protection. The invention is designed to create an LRBL volume that does not need passenger luggage and thus can be standardized. A bomb containment vessel such as FLY-BAG can be surrounded by a halon filled stack of blocks. Many blocks are required to make the protective works on the aircraft and a compressed gas cylinder and valve system are also required.

Bomb blast containment structures include honeycomb or rigid structures that have holes or inclusions in them. The inclusions cause the material to be crushed and thus absorb explosive energy (U.S. Pat. Pub. 2020/0189154). The structures of the matrix material can be made of aluminum. Those materials are also impact resistant because they distribute the force. In the case of the referenced patent, water, oil, or silicone fills the spaces of the matrix structure. The fluids are not dilatant fluids. The matrix structures are rigid and inflexible. A proposed utilization is in helmets and blast panels.

There are many examples of multi-layered blast walls or panels that provide antiballistic protection that are rigid and do not contain fluids. A tripled layered panel includes a crushable honeycomb (U.S. Pat. No. 7,601,654). Another such example is a triple-wall interlocking panel made from layers of least one aluminum material layer, at least one ethylene vinyl acetate material layer, and at least one granite material layer (U.S. Pat. Pub. 2016/0102471). The structures composed of those materials are dense, heavy, take up considerable volume and are inflexible. Another invention makes panels that integrate an assembly formed with aerogels and frangible components. The basic configuration forms a space between an object to be protected and a bomb (U.S. Pat. No. 8,590,437). Those rigid wall systems and panel systems provide good blast, anti-ballistic, and impact protection.

One solution to blast and ballistic protection is to create a composite material which includes microparticles (U.S. Pat. No. 9,060,560). The composite material generally includes a gradient layer structure of a sequence of about three or more gradient-contributing layers of microscale particles, wherein a mean particle size of particles of neighboring gradient-contributing layers in the cross section of the gradient layer structure varies from layer to layer, thereby forming a particle size gradient, and in contact with the gradient layer structure, a densely packed particle structure including densely packed microscale particles, wherein a mean particle size of the densely packed microscale particles does not form a particle size gradient in the cross section of the densely packed particle structure. The microparticles can be encased in a cast material. The principle is that the blast waves will be redirected, dispersed and absorbed by the particle structure.

Other devices use microparticles. In one such apparatus, the microparticles are suspended in liquid and used in a flexible body armor (U.S. Pat. No. 8,201,488). The outer layer was an aramid fiber. The inner layer was a rubber that is conformable and self-healing. The two layers formed a shell. The shell is filled preferably with multiplicity of ceramic particles disposed in a fluid. The particles were ‘T’ shaped that promoted dilatant properties and the material was viscoelastic. The hard ceramic particles cause significant deformation and fragmentation of bullets.

Another concept to retrofit on vehicles including aircraft are blast mitigating material that can be incorporated between flexible sheets to form blast-mitigating assemblies (U.S. Pat. No. 7,520,223). The material can be an aggregate of vermiculate or metal foams, porous materials, or concrete. There can be incorporated fragment stopping materials such as steel plates.

One apparatus proposes both blast mitigation and fire suppression (U.S. Pat. No. 5,390,580). It is an explosive and lightweight container comprising fire-extinguishing and has energy absorbing components. The fire extinguishing component includes an exterior vented plate; a honeycomb element filled with a fire extinguishing agent and separated from the vented plate by a membrane to prevent leakage and contamination. The energy absorbing component includes an energy absorbing material; pusher plate; and a honeycomb crush element. In operation, any blast and conflagration are mitigated by energy absorbing material and fire extinguishing material, respectively.

An aspect addressed herein is the need to address a runaway thermal event caused by chemical reaction and rechargeable batteries. There are systems to contain and suppress fires for battery transport, storage and, including as part of the batteries themselves. Those systems, however, do not provide explosive blast and ballistic protection. Accordingly, there is a need in the art for systems that provide comprehensive safety around the combination of a battery fire (runaway thermal event) and protect against explosive blast and corresponding ballistics.

For background, lithium burns at approximately 2000° C. Glass melts at an average temp. of 1500° C. and steel melts at 1370° C. Appropriate particle materials with high melting points, heat capacity, and ignition temperatures are as follows: graphite melting point 3652° C., and ceramic melting point 2000° C.

There are several examples of rigid cabinets that have monitors for the presence of a fire which triggers spraying of a fire suppressant. They used compressed gas to eject the fire suppressant into the interior volume of the cabinet to cover, for example, lithium-ion batteries (U.S. Pat. No. 10,991,923).

One invention uses a bladder placed in the interior of the battery casing (U.S. Pat. No. 9,478,834). The bladder is filled with a fire suppressing liquid. If there is a fire or heat buildup inside the battery casing, the bladder breaks and the fire suppressing liquid coats the interior, thus snuffing out the fire.

Also provided are unique blankets for retarding and suppressing battery fires, as well as reducing risk of such fires, including from lithium-ion battery fires. With the prevalence of e-bikes, electric scooters, and other personal transportation devices that are rechargeable and portable, the risk of run-away battery fires due to damaged or faulty batteries, has been increasing. Because a thermal run-away lithium ion battery cannot be treated with water, such fires can have expensive and tragic outcomes. There is a need in the art to reduce the risk of such battery fires, and also to have an effective and safe means to suppress and retard an ongoing battery fire. This problem is addressed herein by a special configuration of fire-retardant material and a fire suppressive material in a blanket configuration so that the blanket can be wrapped around a battery for safer storage of battery-containing devices or for throwability to safely suppress and retard a battery fire at a distance.

### BRIEF SUMMARY

As described above, there is a need in the art to provide comprehensive suppression of thermal runaway events and explosive ballistic events, in a safe, efficient and easy to use manner. The prior art devices are fundamentally deficient in one or more characteristics, which can lead to unsafe and dangerous outcomes. Furthermore, although there may be some common materials and physics principles employed, the prior art devices can have dramatic structural differences than the BAFMA systems described herein.

The BAFMA is a multilayered flexible system composed of composite materials, which will absorb explosive energy and stop fragments. There may be an outermost ballistic aramid fabric layer. There may be a layer of Surface Material attenuating rarefaction technology (SMART) (“SURFACE MATERIAL ATTENUATION OF RAREFACTION SHOCK WAVES TO ENHANCE SHAPED-CHARGES”, US Pat. Pub. 2024/0068767) (incorporated specifically by reference herein for various SMART compositions), optionally adjacent to an outermost ballistic layer. Moving inward in the layer geometry, next there can be a layer of catalytic vapor absorbing and particle filtering material, and the second most inner layer may be a fire-resistant fabric or mat material. The core may have a bladder filled with a fluid body, such as water, salt water, or dilatant fluid/slurry such as a highly efficient energy transfer (HEET) (see, e.g., U.S. Pat. No. 11,187,487 specifically incorporate by reference herein for various HEET compositions). Some of these layers are selected to have more than one blast, thermal, or fragmentation attenuating properties. Peak over-pressure, shock velocity, and pressure duration are reduced and thus the damaging effects of shock impulse are also reduced. In simplified terms, shock impulse is a measure of shock momentum transfer to an object. In addition to attenuating blast effects, the inner layers of the BAFMA absorb heat, confer fire resistance, and are fire retardant by depriving a material, such as lithium, of oxygen. There are several layers that decelerate bomb fragments to include those with sharp edges. The outer-most layer(s) of the BAFMA multi-layered system can be selected based on the application of interest, including for ballistics protection and/or a Faraday layer to attenuate radio-frequency signals.

For example, for ballistics protection, it is preferable at least one of the outermost layers comprises a high strength synthetic fiber material known for their anti-ballistic properties, including but not limited to Kevlar® or Dyneema®, with a thickness selected to stop most bomb fragments. These aramid fiber materials are exemplary; there are other materials that have anti-ballistic properties that can be used. However, high strength aramid fiber materials such as Kevlar are not effective against sharp edges and points that can be present. This is where the fluid body in the bladder and SMART materials are effective. Confined spaces such as aircraft fuselage that are occupied by people can be filled with toxic fumes and oxygen displacing vapors. The BAFMA can have a layer that contains a catalytic material similar to those found in canisters used in air purifying respirators. There are pores in the fire retardant fabric to permit vapors that escape through the fluid filled layer to reach the catalytic zone.

The BAFMA is can be structured similarly to a clam shell; there is a top subassembly that has the same layers as a bottom subassembly. They are sister subcomponents that can operably connect to each other, either directly via mated surfaces, or with an intervening component such as a gasket, but the interface may not be airtight in order to further control the venting of combustion or explosive byproducts. When the BAFMA is deployed, depending on the hazard, an operator can select the fluid body that is most appropriate. In an aircraft, that fluid body is likely water. However, if the scenario involves a decomposing lithium-ion battery from a PED, then a HEET solution can be the fluid body and can further comprise silicone or other fluid that is inert to lithium. This reflects the reality that water can accelerate a lithium thermal runaway event.

In a stowed or “storage configuration”, the BAFMA is relatively flat. For example, no fluid bodies are necessarily in the bladder. The fluids can be stored separately, mixed on-site, or can be harvested for example from water/soda bottles that are available on an aircraft. There may be more than one size for the BAFMA and the different layers may have different volumes (e.g., different layer thickness, different inner volume that the layers surround) to focus on a specific set of hazards. For example, if the BAFMA is used in storage or transport of a lithium battery, it can be more compact because it is not attenuating a blast wave, but rather is preventing a fire. The total mass volume of the fragment stopping and blast absorbing layers can be correspondingly lower. The SMART layer can be thinner or can be removed. The fire-resistant fabric layer adjacent to the bladder can be thickened and the bladder be filled with a fluid body that may be a HEET solution containing, for example, a silicone liquid. The particles used in the liquid preferably have the physical characteristics of high heat capacity, melting point, and ignition temperature. In the case of a blast and fragmentation hazard due to high explosives or an explosive material, the reverse emphasis can be applied, where fire spread is of lower concern but ballistic prevention is desired.

Also provided herein are throwable and/or wrappable blankets useful for suppressing and retarding a battery fire. Also provided are related methods of using such blankets to: reduce risk of a battery fire for personal transportation devices brought into a building (wrappable configuration); and suppress, contain and put out a battery fire in a safe manner by controllably throwing the blanket over the battery fire at a distance.

Also provided herein are blankets with thermal detectors, such as an array of thermistors. In this manner, monitoring and alarm of adverse temperature events, including due to battery damage, is reliably provided. Optionally, under an adverse or dangerous temperature, the blanket with temperature sensors may be operably connected to a safety circuit that automatically cuts-off power to the battery. Also optionally provided is an anti-theft component that alarms for any one or more of blanket removal from device, battery removal from device, device movement, wherein the device may be an e-bike.

The BAFMA and blankets provided herein are configured to contain a hazardous device initiation. “Hazardous device initiation” is used broadly herein, and can include explosive initiation or a runaway thermal event for a battery. The initiation can be either intentional or by accident, reflecting the systems and related methods described herein are versatile and have a range of applications.

In an embodiment, the BAFMA has: a top subassembly and a bottom subassembly, wherein the top subassembly and bottom subassembly are operably connected to form an inner volume configured to contain the hazardous device. Each of the top subassembly and the bottom subassembly independently comprise (e.g., they may or may not have equivalent components, geometries, and the like): a bladder having a bladder volume, wherein the bladder volume can contain a fluid body. In a storage configuration the bladder may be empty. In a deployed configuration, the bladder volume may be filled with fluid body. A plurality of flexible and conformable layers surround the bladder. The layers preferably have a high tensile strength, a high ignition temperature, and a high melting point. In this context, “high” refers to a tensile strength to stop a projectile traveling at 1,000 fps, 2,000 fps and up to 5,000 fps, high ignition temperature is a material that will not burn until temperatures exceed 350° C., high melting point are materials that do not melt until their temperature exceeds 300° C., including selected to functionally achieve device attenuation (bladder degradation to release the fluid body, flame retardant, ejection of ballistic projectiles prevented). The BAFMA is configured such that upon hazardous device initiation of the hazardous device positioned in the inner volume, the bladder is configured to rupture and the fluid body and/or plurality of flexible and conformal layers are configured to provide one or more device safety parameters. Examples of device safety parameters include one or more of:
a blast energy absorption (e.g., the fluid released from the bladder may absorb explosive energy, such as up to 50%-70%); ejected hazardous device fragment(s) deceleration (e.g., a ballistic fiber layer can arrest projectile motion); fire resistance (e.g., combination of body fluid and/or flame retardant layer can smother any flames from spreading outside the BAFMA or blanket; and thermal event suppression (e.g., the body fluid and flame retardant can, individually or in combination reduce thermal runaway such as by reducing or smothering a chemical reaction).

To achieve the desired device safety parameters, a plurality of layers are provided. Examples include: a ballistic fiber, including a ballistic aramid fiber fabric sheet; a SMART layer selected from the group consisting of: rigid polyurethane, a vinyl closed cell foam, a polyvinylchloride foam, and a structural foam; a flame retardant layer, optionally formed from any one or more materials selected from the group consisting of: aramid fibers; basalt fibers, fiberglass; Nomex® meta-aramid, poly(meta-phenyleneisophthalamide); Carbon felt/graphite felt; Ballistic fabrics; Silicone coated fiberglass; Ceramic oxide fibers; and Ceramic impregnated fabrics.

In an embodiment, an outermost layer (e.g., furthest away from the hazardous device), comprises one or more ballistic aramid fiber fabric sheets, including multiple stacked layers of the ballistic sheets. In a preferred embodiment, at least one of the layers comprises a SMART layer.

In an embodiment, at least one of the plurality of layers comprises a filter material and/or a catalytic material.

In an embodiment, provided as one of the layers is a SMART layer comprising a two-part expanding foam. In other words, until the two-parts are mixed with each other, the SMART layer will have a relatively low volume. Upon mixing of the two-parts, the volume expands so that the SMART layer has a relatively high volume. Particular increase in volume can be controlled by selecting the two parts and their relative amounts. The two-part expanding foam may be formed from: a first chemical component positioned within a first cell; a second chemical component positioned in a second cell; a degradable barrier separating the first cell from the second cell. “Degradable barrier” is used broadly herein to include any means wherein fluids can mix. Accordingly, it may be relatively passive, such as with pores. Alternatively, it may be more artificial or active, such as by placement of valves. In the broadest sense, there may be a first chemical component in one cell (e.g., a bladder) and the second chemical component may be actively introduced by piercing the bladder (or a valve therein) to introduce and mix the second chemical with the first chemical. Degradation of the degradable barrier results in mixing the first chemical component with the second chemical component to provide the two-part expanding foam that provides an increase in volume of the SMART layer compared (“deployed configuration) to a SMART layer volume before mixing (“stored configuration”).

The SMART layer optionally has a plurality of SMART elements formed into a lattice, including triangularly shaped elements interconnected by a fiber or rope. In this manner, the SMART layer is further conformable, including the ability to accommodate relatively rigid areas that are interconnected with a fiber or rope that has a relatively higher elasticity (e.g., Young's modulus) and flexibility than the shaped elements.

In an embodiment, the fluid body comprises suspended particles to form a dilatant fluid/slurry material configured to deflect, redirect and absorb a shock wave upon a hazardous device initiation. The particles are optionally selected from the group consisting of: aspherical shape; an asymmetric shape; and an aggregate of sizes defined by the largest dimension.

The SMART material may be formed from a plurality of beads contained by an inner and outer surface that are closed to form a layer, wherein the beads are crushable and selected from a group consisting of: ceramic microbubbles; a rigid polyurethane foam; and a vinyl closed cell foam.

Holes or passages may be formed in one of the plurality of layers that is the flame-retardant layer. This facilitates passage of vapors and suspended particles between adjacent layers. Examples of particles include, for example: ceramic microspheres; natural sand; graphite; glass microspheres; sodium bicarbonate powder; Silicone; monoammonium phosphate; ammonium sulfate; and any combination thereof.

The BAFMA is compatible with other components, including to facilitate handling of the BAFMA. The BAFMA may include handles and a locking mechanism to operably connect the opposing top and bottom subassemblies. The locking mechanism may be selected from a group consisting of a plurality of: straps with buckles; locking pins; straps with clips; hook-and-loop fastener straps.

Each of the top and bottom subassemblies may further comprise component(s) that functionally provide jamming of electromagnetic communication to/from a device that is covered by the BAFMA or a blanket. For example, an active jammer may be incorporated into a layer, wherein active jammer refers to an electronic device that radiates at radio and microwave frequencies to overwhelm a receiver such that it will not respond to a command signal or the jammer adds digital information to make an incoming digital signal unreadable. Active jammers can transmit at specific frequencies simultaneously or when a signal is detected, radiate at the detected signal frequency. Of course, the invention is compatible with more passive jamming. Accordingly, at least one layer in the subassemblies may be one or more of: a faraday fabric layer for electromagnetic communication attenuation with the hazardous device; an electrical network forming an inner layer that surrounds the bladder, the electrical network configured to provide continuous broadband attenuation of electromagnetic radiation by absorption, reflection, and dispersion, including formed from a conductive and capacitive filler having a thickness selected for a user-desired attenuation level and frequency range, including between 1 kHz and 100 GHz; and/or the fluid body comprising an electrically conductive filler having a defined capacitance to attenuate electromagnetic radiation by absorption, reflection, and dispersion to a user-desired attenuation level and frequency range including between 1 kHz and 100 GHz. Connection of the top and bottom sub-assemblies fully encapsulates the inner volume and blocks an electromagnetic signal to/from the hazardous device positioned in the inner volume formed between the two sub-assemblies. In this context, the operably connected top and bottom subassemblies refers to an encapsulation such that certain electromagnetic fields corresponding to wavelength ranges were signals are typically transmitted or received, are blocked, in a manner equivalent to a Faraday cage.

The BAFMA may have a capsule shape.

The BAFMA may have a bladder with a one-way single flow valve, including to accommodate filling of the bladder volume with a fluid body.

The plurality of layers are formed of a material(s) selected to control at least one of the following containment parameters: blast peak overpressure; blast shock impulse; fragmentation; flame; thermal runaway. Depending on the application of interest (e.g., wrapping an e-bike battery versus containing an IED), the plurality of layers with attendant containment parameters, are selected accordingly.

Provided herein are methods of using any of the BAFMA's described herein. For example, the method may be to attenuate a hazardous device initiation by providing any of the BAFMAs described herein and positioning a fluid body in each of the bladder volumes, including by introducing the fluid body into the bladder volumes, such as via a sealable valve. The hazardous device is placed in the inner volume formed by the top and bottom subassemblies that are operably connected. In this manner, attenuating the hazardous device initiation is achieved, including for an attenuation comprising one or more of: blast attenuation, fragment mitigation, fire suppression, fire retardation, and vapor neutralization. The attenuation may be complete or partially complete, such as an at least 50%, at least 75% or at least 95% attenuation. Depending on the parameter associated with the attenuation, the attenuation may be a time (e.g., time for a flame to spread), or may be a physical parameter (explosive force, temperature external to the BAFMA, ballistic projectile velocity or acceleration).

The method may further comprise the step of selecting one or more of the plurality of layers to control at least one containment parameter selected from the group consisting of: a blast peak overpressure; a blast shock impulse; a fragmentation velocity; a flame; and a thermal runaway.

Also provided are methods of making any of the BAFMA's described herein.

Also provided herein are fire extinguishing (or preventing) blankets having: a layer comprising a fire retardant material with an inner surface and an outer surface separated by a thickness of the layer and a pouch connected to the layer inner surface that defines a pouch volume. A fire extinguishing material is positioned in the pouch volume, the fire extinguishing material comprising a chemical, including a dry chemical or a fluid chemical such as silicone, to suppress a rechargeable battery fire. The pouch is at least partially formed of a pouch material that degrades at a fire release temperature to release the fire extinguishing material. In this manner, the blanket has an automatically build in dual functionality of: (1) suppressing or preventing a fire at a “relatively” low temperature via release of the fire extinguishing material at a lower than a fire temperature; and (2) prevent a fire spread by the fire retardant material that remains intact at even higher temperatures corresponding, for example, to when a fire is present. The blanket may be characterized as a “throwable” (throw at a distance to cover a device) or a “wrappable” blanket. A throwable blanket preferably has a weighted material positioned in a perimeter region of the layer, the weighted material having a density greater than a layer density and fire extinguishing material density, wherein the weighted material is configured to improve an aerodynamic parameter and thereby provide the fire extinguishing blanket that is controllably throwable. The “perimeter” region refers to corners and edges of the blanket, such as the outermost about 1 cm to 10 cm region of the blanket.

For a wrappable blanket (blanket wrapped around the device), preferably one or more fasteners are connected to the fire retardant material outer surface and/or fire extinguishing material layer, wherein the fasteners are configured to provide a blanket open configuration and a blanket wrapped configuration sized to contain a rechargeable battery and thereby provide the fire extinguishing blanket that is wrappable. The fasteners may be a Velcro® (hook and fastener) type mechanism, snap buttons, zippers, buttons and the like.

The blanket is compatible with a range of fire retardant materials. Examples include, but are not limited to, aramid fibers; fiberglass; the fire extinguishing material is selected from the group consisting of aramid fibers; fiberglass; Nomex® meta-aramid, poly(meta-phenyleneisophthalamide); carbon felt or graphite felt; a ballistic fabric; silicone coated fiberglass; ceramic oxide fibers; and ceramic impregnated fabrics

The blanket is compatible with a range of fire extinguishing materials. Examples include, but are not limited to, sodium bicarbonate; silicone; monoammonium phosphate; and ammonium sulfate.

For the throwable blanket, the aerodynamic parameter may correspond to a throw distance that is 20 feet or greater, with a reliable ability of a trained user to cover a device from a distance that is 20 feet or greater, such as more than 50%, 70% or 90% of the time, for a distance, for example, between 20 feet and 50 feet.

The fire extinguishing blanket pouch may comprise: an outer wall formed of the fire retardant material; and an inner wall formed from an inner sheet, including a cloth or plastic sheet. The pouch is configured to release the fire extinguishing material at a temperature that is greater than or equal to a fire release temperature. For example, the pouch may sufficiently degrade at a temperature above about 250° C., 300° C., 400° C. or 600° C., including between 250° C. and 350° C. In contrast, the fire retardant layer or material is selected to remain functionally intact at higher temperatures than a degradable layer, bladder or other component that is intended to degrade and release a material (such as from a pouch or a bladder) to suppress or prevent a fire. For example, the fire retardant material may remain functionally intact at temperatures at or above 500° C., such as between 600° C. to 1200° C. A pouch, bladder, or other material that contains a fire extinguishing material (including a fluid body, or chemical) degrades at a temperature that is lower than any degradation of a fire retardant material layer. This aligns with the dual functionality of the BAFMA/blankets provided herein, with one component (bladder containing fluid or pouch containing fire suppressant material) intended to prevent and suppress a fire, and the other component (e.g., fire retardant layer) intended to delay spread of a fire to the surrounding environment. Similarly, other layers, such as a ballistic fabric layer, can also be selected to remain intact at temperatures above 500° C., specifically for those layers where functionality is desirable even after a flame event initiation.

The fire extinguishing blanket may have an aerodynamic parameter that is a throw distance, including a throw distance that is 20 feet or greater, such as between 20 feet and 50 feet.

The device that is a rechargeable battery may be a lithium-ion battery, alkaline battery, nickel metal hydride battery, lead acid battery, lithium polymer battery, nickel-cadmium, lithium iron phosphate, or zinc carbide battery. The rechargeable battery may be mounted to a vehicle body, including a bicycle frame. This is a relevant aspect in view of the risk of a battery fire for a car parked in a residential garage or an e-bike that is stored near or in a residence.

The fire extinguishing blanket may comprise a multi-layer configuration, with the layer that is actually a plurality of distinct layers, with different layers providing different functionality ranging from ballistic control, thermal runway, fire suppressant and fire retardant.

Any of the fire extinguishing blankets may be used to suppress and retard a rechargeable battery fire, including by: throwing the controllably throwable fire extinguishing blanket over the rechargeable battery fire; or wrapping the wrappable fire extinguishing blanket over a rechargeable battery at risk of a rechargeable battery fire.

Also provided are blankets to contain a hazardous device initiation. The blanket may comprise: a plurality of layers comprising: a flexible and conformable outer ballistic layer configured to conform to a device shape, the flexible and conformable outer ballistic layer formed from a material selected to have a tensile strength, an ignition temperature, and melting point to absorb and withstand device initiation without failure; and a flame retardant inner layer to retard or suppress a flame; wherein upon device initiation the plurality of layers are configured to: absorb a blast energy; stop ejected fragments; resist a fire; retard a fire; and/or suppress a thermal event.

The blanket of may further comprise: an array of temperature sensors connected to at least one surface of the plurality of surfaces, wherein the array of temperature sensors are configured to measure a temperature of the hazardous device that comprises a battery; an alarm operably connected to the array of temperature sensors to generate a warning of an adverse battery temperature event indicative of an initiation risk corresponding to a battery thermal runaway; and optionally, a rechargeable battery cut-off having an actuatable switch configured to open upon the adverse battery temperature event.

The blanket may be configured to electronically isolate a covered device from an electromagnetic spectrum range that corresponds to a signal frequency. For this aspect, the plurality layers may also comprise: a faraday fabric layer for electromagnetic communication attenuation with the hazardous device; an electrical network configured for continuous broadband attenuation of electromagnetic radiation by absorption, reflection, and dispersion; and/or a fluid body contained in a bladder, wherein the fluid body comprises an electrically conductive filler having a defined capacitance to attenuate electromagnetic radiation by absorption, reflection, and dispersion.

Also provided herein are methods of attenuating an electromagnetic signal to prevent a hazardous device from receiving an electromagnetic signal to initiate the device using any of the BAFMA or blankets provided herein, including by one of: throwing the blanket over a hazardous device; wrapping the wrappable blanket over a hazardous device; or remotely placing the hazardous device atop the blanket and entirely covering the hazardous device with the blanket.

### BRIEF DESCRIPTION OF THE DRAWINGS

FIG. 1 illustrates the BAFMA in the stowed configuration (left—no fluid body in bladder) and the deployed configuration (right—fluid body in the bladder).

FIG. 2 illustrates a sectioned view of the deployed BAFMA configuration. The layers are more visible in detail ‘E’.

FIG. 3 illustrates a bisection along the central long axis plane. Pores in the flame-resistant fabric are shown.

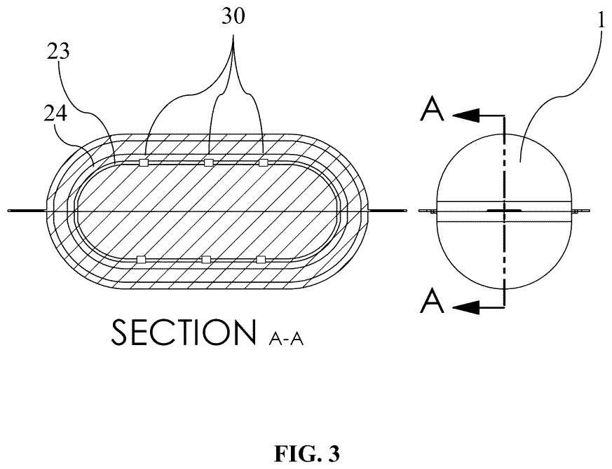

FIG. 4A illustrates the steps of loading an electric bicycle lithium ion battery into the BAFMA and then closing and locking the subassemblies.

FIG. 4B is a side view and sectioned side view of the configuration shown in FIG. 4A.

FIG. 5 illustrates a partially sectioned view of a deployed BAFMA revealing a device placed in the inner volume, in this example a bomb.

FIG. 6 illustrates one of the two bladders inside of a BAFMA. There is a neck with a hole and a plug to facilitate filling and fluidically sealing of the bladder. In an embodiment, a compressed sponge layer material may be used to help assist with bladder fidelity and leakage risk management.

FIGS. 7A-7C illustrates different liquids, including that can be positioned in a bladder or a pouch blanket. FIG. 7A shows a liquid with no particles such as water. FIG. 7B shows a liquid such as silicone that has uniform particles mixed into it. FIG. 7C shows a fluid that has an aggregate of particles of different size to increase compaction and the dilatant dynamic viscosity.

FIG. 8 illustrates an aircraft with an LRBL location identified. The bottom drawing is a transverse section of the fuselage at the LRBL. The BAFMA is embedded inside a mound of luggage and clothing at the LRBL.

FIG. 9 illustrates a portion of a lattice subassembly of the SMART material triangular sheet units that are mated with high strength fiber or rope such as Dyneema. The rope passes through the SMART material and facilitates SMART layer conformability.

FIG. 10 is an example of a battery network, including rechargeable batteries, having three cells.

FIG. 11A is a battery blanket embodiment with perimeter weights and pouches on the underside of the fire retardant layer filled with a fire suppressant material. FIG. 11B is another embodiment wherein the fire suppressant material is provided as an additional layer connected to the fire retardant layer.

FIG. 12A illustrates a throwable fire extinguishing blanket that is being thrown similar to a sports disk (e.g., rotation and translation) over batteries in thermal runaway. The arrow indicates the throw distance. FIG. 12B illustrates the throwable fire extinguishing blanket that covers the batteries in thermal runaway after throwing, thereby both retarding any flames and suppressing the chemical reaction.

FIG. 13A illustrates an e-bike, with the battery affixed to the bike frame. FIG. 13B illustrates a wrappable fire extinguishing blanket that wraps the battery, thereby retarding, extinguishing, and preventing a battery fire, including for when an e-bike is stored in a building.

FIG. 14 is a cross-sectional cutaway view of a blanket wrapped battery showing the outer layer of fire retardant fabric and an inner layer (in this illustration in pouch form) of a fire suppressant material.

FIG. 15 illustrates the weighted perimeter region that provides an improved aerodynamic parameter to facilitate throwability of the blanket with respect to a target battery fire.

FIG. 16 illustrates the blanket of FIG. 15 with a variety of add-on features, including array of temperature sensors, circuit cut-off, alarm, and anti-theft component.

FIG. 17 illustrates deployment by controlled deployment of the blanket over a battery-containing target (in this example a laptop computer) that is on fire or at risk of fire. The blanket may be thrown like a Frisbee disk with a controlled rotation motion of dragged by a drag line connected to the blanket to thereby cover a burning rechargeable battery, including a Li-ion battery.

FIG. 18 illustrates a Thermal and Alarm Monitoring Unit (TAMU) connected to a blanket (LIFEx™). In this example, the blanket is wrapped around an e-bike battery and bike battery harness.

FIG. 19A (top left panel) illustrates a top view of the blanket ballistic/fire retardant layer in an unwrapped configuration, with hook-and-loop strips (including Velcro® fasteners), configured to, upon deployment, wrap or cover a battery. The top-right, bottom left, bottom rights panels are an isometric view, front view and side view, respectively. FIG. 19B is a blanket bottom view illustrating a thermistor array with wires attached to the thermally sensitive pouch which contains the fire suppressant. The TAMU can have a pipe at its center that channels the wires.

FIG. 20A is a close-up top view of the TAMU thermistor array. For clarity, the blanket is not illustrated. The TAMU can connect to battery without blanket. Magnets, straps, or adhesives are used to operably connect the TAMU to a battery. FIG. 20B is a side view. FIG. 20C is a bottom view.

FIG. 21A is a side view close-up view of the TAMU without a blanket. FIG. 21B is a top view.

FIG. 22A is a top view of the TAMU with the lid removed. FIG. 22B is the same view of FIG. 22A, but with the indicator lights removed to reveal the TAMU analysis, logic, and control circuit board.

FIG. 23 is a flow-chart schematic of a decision tree for a thermal alarm circuit of a TAMU to indicate nominal (acceptable) battery temperature (e.g., a green light), warm temperature (e.g., yellow light), or potentially dangerous temperature indicative of high risk of imminent thermal runaway (red light/audible alarm).

FIG. 24 is a flow-chart schematic of a decision tree for an anti-theft alarm circuit of a TAMU.

FIG. 25 illustrates a two-part expanding foam that may form a SMART layer. Each of the two-parts are initially contained in separate compartments, labeled Component A and Component B, with the illustrated embodiment having a barrier configured to controllably rupture or a two-way valve to fluidically mix the two-parts with each other. The middle panel illustrates the two-parts mixed together. The bottom panel illustrates, after mixing the two-parts there is an expansion in volume. Functionally, the barrier can correspond to a puncture or rupture due to pressure applied, or opening a valve.

FIG. 26 illustrates an RF-attenuating embodiment, with one of the outer layers comprising a Faraday Fabric that, in turn, may be wrapped with a ballistic fabric layer. The blanket may be wrapped or thrown, thereby covering a target. In this case, the target is illustrated as resting on a surface. The blanket may be conformable, including by a weighted perimeter that ensures there is no openings between target and surrounding environment, thereby protecting against ballistics, fire and/or RF leakage. Similarly, the BAFMA (see, e.g., claim 1) may have subassemblies with equivalent layers for electromagnetic spectrum isolation.

FIG. 27 illustrates another embodiment wherein the target is sandwiched or wrapped between two blankets, each having RF attenuating bodies. A robot may be used to remotely move the hazardous device, such as placing it atop a first RF attenuating blanket and ready to be covered with a second RF attenuating blanket. RF attenuating Blanket can be wrapped or thrown, and may correspond to a BAFMA having the top and bottom subassemblies. There is conformability to the ground and device outer-facing surface(s), and may have the weighted perimeter to insure no leakage of RF. The hazardous device may be a confirmed bomb or suspect package, illustrated as sandwiched or wrapped with two RF attenuating bodies. A robot can remotely move the device and place it atop a RF attenuating blanket.

### DETAILED DESCRIPTION

The terms IED, hazardous device, bomb, and ordnance are used interchangeably herein.

“SMART” refers to a surface material attenuation of rarefaction shock waves material, including those materials described in US Pat. Pub. 2024/0068767, which is specifically incorporated by reference herein. In particular, a SMART material is an attenuating body configured to impact reflected shock waves that are otherwise propagated in the contained liquid and interact with liquid/wall interfaces. One example of a SMART material is foam. “Foam” refers to a material that is formed by trapping pockets of gas in a liquid or a solid. A solid foam can be closed-cell or open-cell, depending on whether the pockets are completely surrounded by the solid material. In an open-cell foam, gas pockets connect to each other, including via pores. In a closed-cell, gas pockets are not connected to each other. The foam is polydisperse and is characterized as not uniform and stochastic. Foams efficiently attenuate shockwaves because of the heterogeneous structure in combination with low bulk density. In this manner, pressure waves are broken up and dispersed, thereby providing good shock tamping. Depending on the application of interest, which influences the desired liquid jet characteristics, the foam can be made from any of a range of materials, such as plastic, rubber (natural or synthetic), aluminum or other metals. The foam can be rigid polyurethane, a vinyl closed cell foam, a polyvinylchloride foam, and a structural foam. For example, blasting cap protectors are made from aluminum foam because aluminum foam absorbs the shock when crushed under pressure. The attenuating body may also be an aerogel. “Aerogel” refers to a synthetic porous material derived from a gel, where the liquid component has been replaced with a gas without significant collapse of the gel structure. Exemplary aerogels include, but are not limited to, solid smoke, solid air, solid cloud, blue smoke, silica aerogels, carbon aerogels, polymer-based aerogels, metal-oxide aerogels, and the like. The attenuating body may be a two-part foam, wherein two chemical precursors are mixed with each other to generate a volume-expanding foam.

“Operably connected” refers to a configuration of elements, wherein an action or reaction of one element affects another element, but in a manner that preserves each element's functionality. For example, a top subassembly is operably connected to a bottom subassembly such that an inner volume is defined in which a hazardous device can be placed, without adversely impacting the components, including the plurality of layers, in the subassemblies. The connection may be by a direct physical contact between elements. The connection may be indirect, with another element that indirectly connects the operably connected elements.

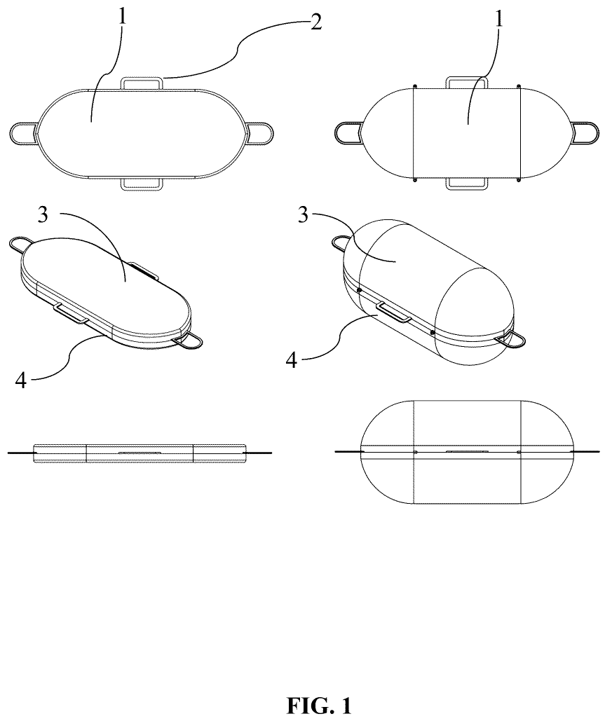

Bomb technicians and EOD technicians responding to an item suspected to be a bomb or confirmed IED may need to transport the device to a second location to render it safe. Emergency responders can use the BAFMA 1 in place of conventional transport devices (FIG. 1). It is lightweight and covers a wide range of hazards of concern to a responder. Bomb technicians may need to neutralize a bomb in place. The bomb may be near critical infrastructure. The BAFMA can be opened and positioned so that the top 3 and bottom 4 halves form a ‘V’ shaped opening. A high explosive mass focusing disrupter can be placed within the central area of the ‘V’. The BAFMA will not impede the disrupter jet because it passes through the mouth of the ‘V’. The back blast and disrupter fragments are impeded by the BAFMA.

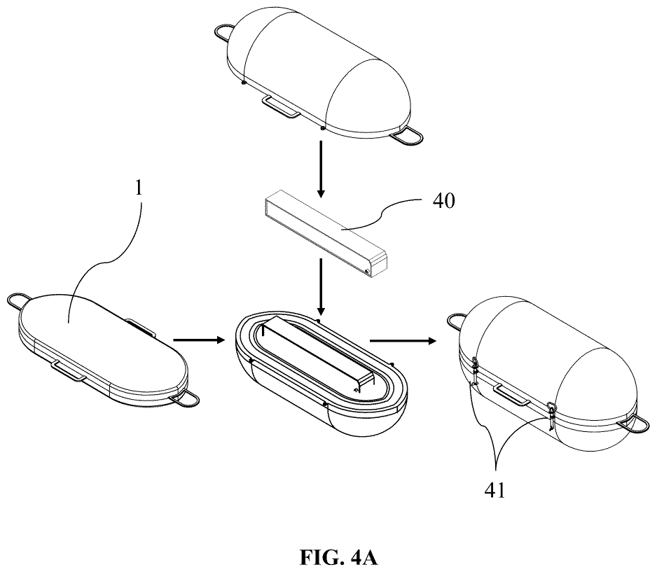

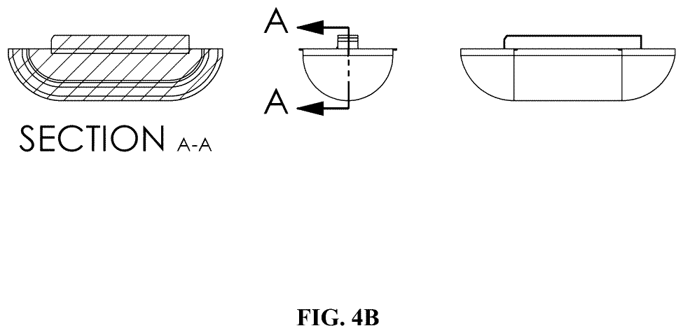

The BAFMA can have handles 2 for transport. A set of handles are on its longitudinal ends so that it can be dragged by a robot or using a tow line. Another set of handles are at the sides, and it can be lifted for placement on a transport bed. The clam shell need not be airtight to promote venting and one mechanism to connect the top and bottom is using locking pins 40 (FIG. 4) that can later be pulled out by a robot or semi-remotely using a line. The locking pins are used as an example and not meant to limit the locking options. Someone knowledgeable in the art may use pull straps with clips or pass through locking buckles may also be used to close the BAFMA. Velcro straps can also function effectively. These mechanisms can be manually opened or a razor cut line hook from a EOD hook-and-line kit can be used to semi-remotely cut the straps.

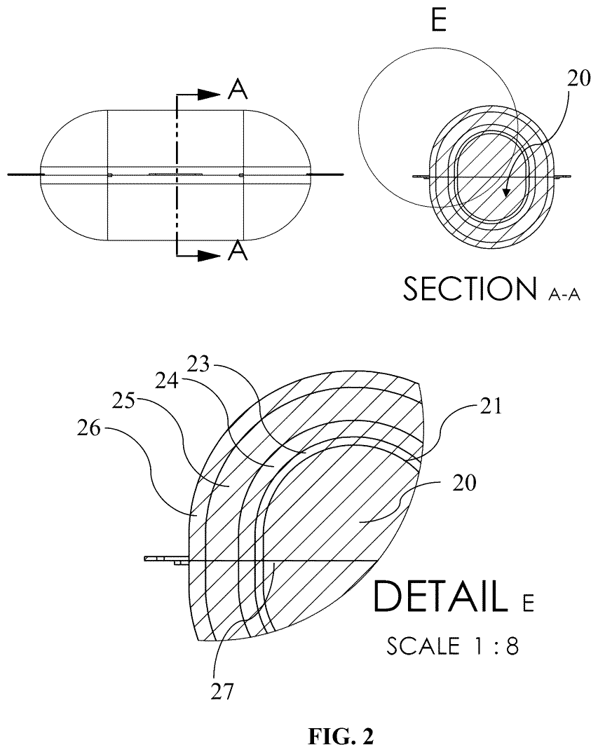

Functions of each BAFMA layered volume will be expanded upon (FIG. 2). Each layer has an inner surface and an outer surface that have material between them, which define the boundaries of a conformable layer volume. We will begin starting from the inner-most layer volume and then proceed outward from the core. The top 3 and bottom 4 subassemblies can be identical and in operable contact with each other, including in intimate contact along a plane 27. This contact zone is not airtight. A detailed view ‘E’ is a magnification of the transversely sectioned BAFMA.

The inner volume formed by the top and bottom subassemblies may contain a fluid body 20 that is contained in a bladder 21. The fluid body can be a HEET fluid, water, or salt water. If there is a device explosion, the capsule shape promotes a rapid drop in fluid density and increased droplet formation. The size of the droplets is related to their viscosity and described by a Weber number. The fluid density follows an inverse square law with distance from the center if the content is a bomb that detonates. The bladder is ruptured due to the blast and heat. The explosion releases its energy in waves known as bubble energy and high-speed videography shows the bubble expanding and contracting. There are waves of water jets referred to as spatial jets due to the small droplets that are jetted. The explosive gases are trapped by the liquid. A dilatant material is inhomogeneous which deflects, redirects and absorbs the shocks. More than 50% of the explosive energy is absorbed by the liquid. Due to the high heat capacity, high compressive strength of liquids such as water or silicone, the temperature of the liquid does not change significantly during the event which takes place in a couple of milliseconds.

Without the other blast attenuating layers, a cylindrical water volume required for a 1 lb. charge is calculated to be approximately 7.2 gal for pressure to drop to 5 psi at 15 feet from the charge. The maximum recommended blast overpressure exposure with minimal injury with composition C-4 explosives for a spherical charge is approximately 4 psi. It is estimated that no more than 1 gallon to 4 gallons per bladder would be required when combining the bladder with the SMART material or water based-foam layer. Using HEET mixtures, the volume can be reduced between 25% and 50% compared to water.

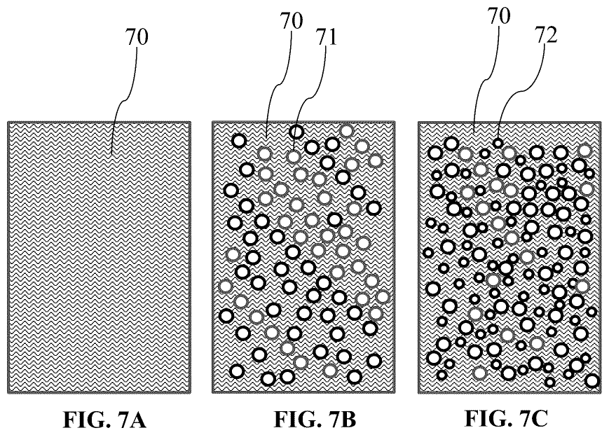

Water and HEET fluids are effective at decelerating bomb fragments. FIG. 7A-7C shows the different fluid classes that can be placed in the BAFMA bladders. FIG. 7A graphically shows a Newtonian liquid 70 such as water, salt water, or pure silicone. Salt water has a higher density than deionized or tap water, which will be more efficient at absorbing explosive energy and have a slower spatial jet. Salt water is also known to suppress flames. It must be noted that water will violently react with lithium and accelerate a lithium fire. Alternatively, silicone is relatively inert and does not react with lithium. Silicone used for transport in the event of a fire can coat and smother a burning battery for example. The silicone can deprive the battery of oxygen. Pure silicone fluid can be mixed with particles to form dilatant materials, which will become viscoelastic and increase the drag coefficient of a fragment thus decelerating it. The particles should be small, ranging in size from 50 microns to 1,500 microns. FIG. 7B shows particles 71 that are uniform in size. FIG. 7C illustrates a fluid that has an aggregate of particles sizes 72 mixed in. Aggregates can be packed more densely and thus have higher effective viscosities. Ceramic microspheres and glass microspheres can also be used as particles. Ceramic is extremely hard and has extremely high heat capacity and melting points. It will confer great ballistic properties to the HEET fluid. Natural sand has a range of particle sizes and non-spherical shapes. These shapes promote interlocking of the particles under compression and the material becomes more solid compared to an aggregate with spherically shaped particles. Particles can also be fire suppressants such as sodium bicarbonate powder. Graphite powder is also a good material for particles. It may also be used in the fire-retardant layer described below.

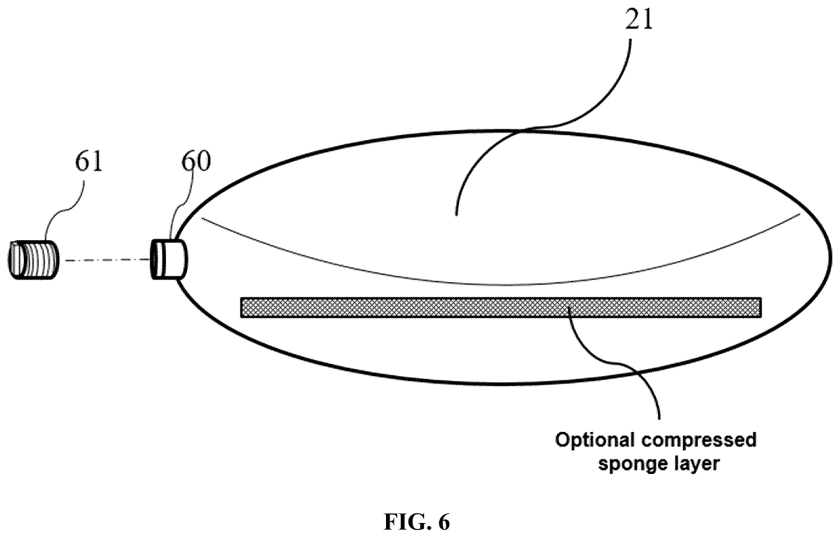

The fluids may be contained in a bladder (FIG. 6) that ruptures when in the presence of an explosion or heat. The bladder 21 has a fill port, which has a neck 60 that can extend to the outside when the BAFMA is closed. The fill port may have a one-way valve to allow liquid to enter but no leak out. Optionally, the bladders of the top and bottom subassemblies can be filled separately. A plug 61 fluidically seals the bladder.

Leakage of the bladder is always a concern. This is addressed herein in two ways. First, a puncture resistant liner on the surface of the bladder. Second, compressed sponges, such as for example cellulose, can be positioned inside the bladder (FIG. 6). When filling the bladder with fluid, the sponges absorb the fluid and expand between two and 10 times their volume. The sponges trap the fluid and prevent leakage of the fluid even if the bladder wall is compromised. Other embodiments may use a solid gel material, such as sodium polyacrylate, that absorbs the fluid, or a diaper construction.

Surrounding the bladder is a layer of fire-resistant fabric 23 such as fiberglass. The fabric can withstand high temperatures and prevents heat transfer to the outer layers. There are pores or channels in the fire-resistant layer to allow for explosive gases, combustion byproducts or vapors to pass through to the next layer of a catalytic or filter materials 24 to react and absorb the vapors and filter out toxic particles. Examples of catalytic or filter materials are ASZM-TEDA Carbon (activated charcoal), Hopcalite, or Platinum.

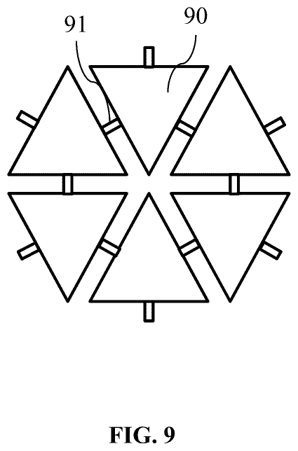

The second to last outermost layer 25 is filled with SMART material. It has a defined thickness. The SMART material attenuates shocks and reflected shocks due to impedance mismatching. The SMART material also erodes the jetting liquid from the core of the BAFMA. The SMART material can be rigid polyurethane foams ranging in density from 8 lbs. per cubic ft. to 15 lbs. per cubic foot. Experiments with SMART have shown it can absorb a focused explosively driven water jet traveling at approximately 2,500 fps-3,000 fps. The jet penetrates the medium 6 inches. The peak velocity of the expanding spatial water jet from a cylindrically shaped system with a 1 lb charge is approximately 1,600 fps. Therefore, the wall thickness of SMART to attenuate the BAFMA jet is a fraction of 6 inches. The SMART layer can be a bag filled with ceramic microbubbles, rigid polyurethane foam beads, rigid vinyl foam beads. The SMART rigid foam can be triangular pieces 90 that are coupled in a matrix using Kevlar or Dyneema rope 91 (FIG. 9).

The outermost layer 26 is a high strength ballistic fabric and can be stacked sheets of Kevlar or Dyneema as species of aramid fabric. They are high tensile strength and are readily deform and stretch. The weaves in the fabric tighten to stop a projectile such as a bomb fragment. These materials are also fire resistant. The fabric weave is not airtight which will aid in controllably venting explosive byproducts, or combustion gases. Bomb suits have very thick layers of these materials and can absorb and disperse blast waves and stop bomb fragments. The BAFMA outer layer will do the same.

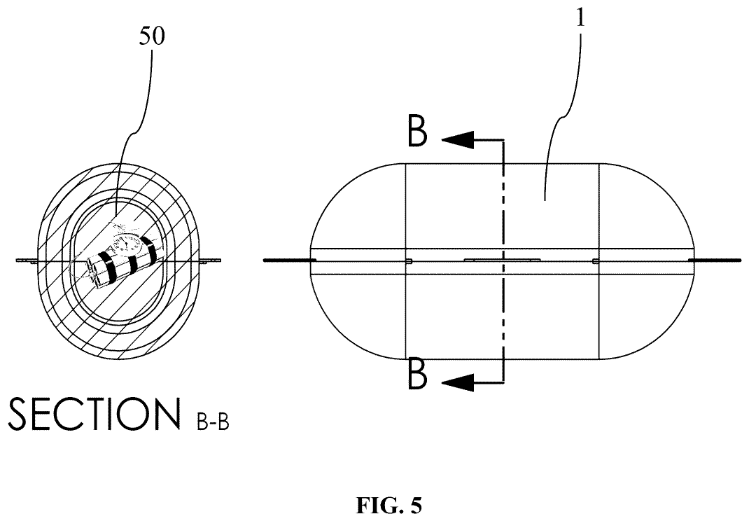

A practical example of the BAFMA being used is shown in (FIGS. 4A and 4B). The figure illustrates the steps of configuration a lithium-ion bicycle battery 40 inside a BAFMA for storage or transport. The BAFMA is opened. The bladders in the top and bottom subassemblies are filled with silicone or HEET fluid containing silicone. The top bladder can be filled later. The battery is seated onto the bottom fluid filled bladder. The battery causes a depression (section A-A FIG. 4B) as the bladder acts as a shock cushion and protects the battery from impacts. The top bladder can be placed over the battery and then filled with fluid. The remaining portion of the top subassembly is put in place. The locking mechanism, in this case locking pins 41 are set in place. The BAFMA is now ready for transport. FIG. 5 shows a partial transverse sectioning of a deployed BAFMA containing an IED 50.

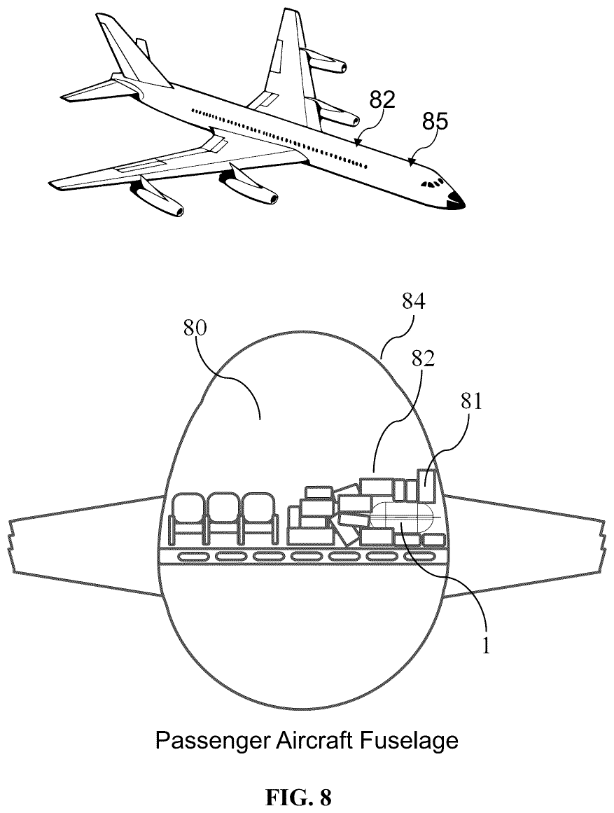

FIG. 8 shows an operational scenario of a bomb on a passenger aircraft 85. The figure shows a transverse section of the plane as outlined by the skin 84. An IED 50 is discovered on board in the passenger area 80. The pre-deployed configured BAFMA is removed from storage. In this case, the fluid will be water from the available water bottles. The aircraft staff will construct an LRBL 82 using available luggage and clothing 81 and at the same time deploy a BAFMA 1 and place the bomb 50 inside. When the LRBL is 50% completed, the BAFMA will be lifted and put on the pile of baggage and clothes. The BAFMA is then buried in the mound. The BAFMA can be oriented, so the blast is directionalized.

### Example 1: Fire Extinguishing Blankets

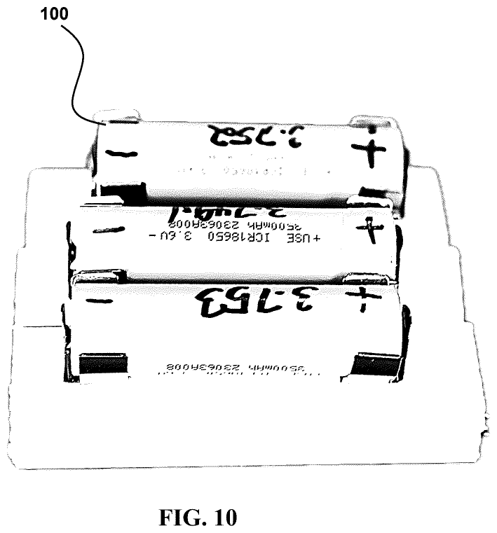

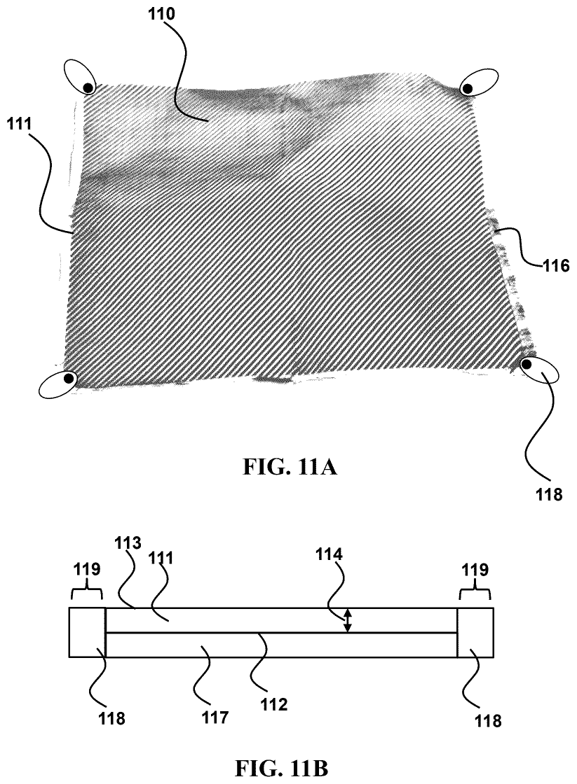

Referring to FIGS. 10-16, provided herein are throwable and wrappable fire extinguishing blankets useful for containing fires that cannot be extinguished by water. FIG. 10 illustrates batteries 100, in this figure a battery network of three cells. This may be three lithium-ion batteries. FIGS. 11A-11B illustrate throwable fire extinguishing blanket 110 having a layer of fire retardant material 111 (e.g., a fabric) with an inner surface 112 and an outer surface 113 separated by a thickness 114. A fire suppressant material 115 may be provided in pouches 116 (FIG. 11A) or as a separate layer 117. The pouches or layer are configured to degrade at high temperatures to effectively “release” the fire suppressant material and smother any fire. The fire suppressant material may comprise the material that is provided in a dry chemical fire extinguisher. The heat produced by the batteries in thermal runaway causes the enclosing material to fail, including pouches that contain the fire suppressant material, which releases the fire suppressant material in a manner that effectively smothers the burning battery, preventing oxygen from feeding the battery-caused fire, thereby extinguishing the battery fire. In this manner, the special configuration of the layer of fire retardant material 111 ensures the fire suppressant material 115 is positioned over the battery so that upon fire, the suppressant material 115 is released directly over the battery.

A weighted material 118 may be positioned in a perimeter region 119 of the fire retardant material 111. This weighted material helps improve the throwability, including by improving an aerodynamic parameter of the blanket. “Aerodynamic parameter” is used broadly to characterize the blanket as throwable. It may be a throwable distance. For example, non-weighted blankets do not have the aerodynamic characteristics so that the blanket can be reliably thrown at a distance to cover a target. The throwable distance may be an absolute distance, such as 10′ or greater, 20′ or greater, or 50′ or greater, including a range of between 10′ and 100′ and any subranges thereof, such as between about 20′ and 50′.

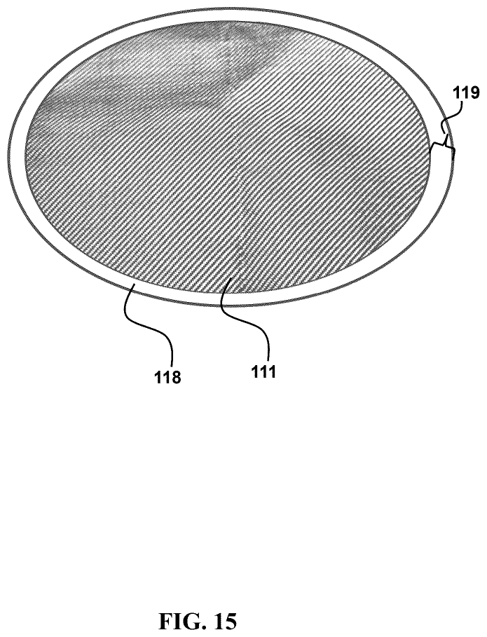

FIG. 15 illustrates the weighted perimeter region 119 may include a relatively dense (e.g., 1-12 g/cm³) rod or tube filled with particulate/powdered dense metal (lead, steel shot, copper, bismuth, tungsten or bronze), rubber, or plastic. The perimeter region is operably connected to the fire-retardant layer. The operable connection is used broadly in that the connection may be a loop of fire retardant textile in which a flexible tube is contained. Alternatively, the perimeter region may be a separate material that is fastened to the fire retardant material. The end result, irrespective of the operable connection, is that there is an aerodynamic configuration similar to a Frisbee® disk, where a user throws the blanket is a spinning or rotating manner to a desired target that can be a runaway battery fire to which the fire retardant material and fire suppressant material are “matched”.

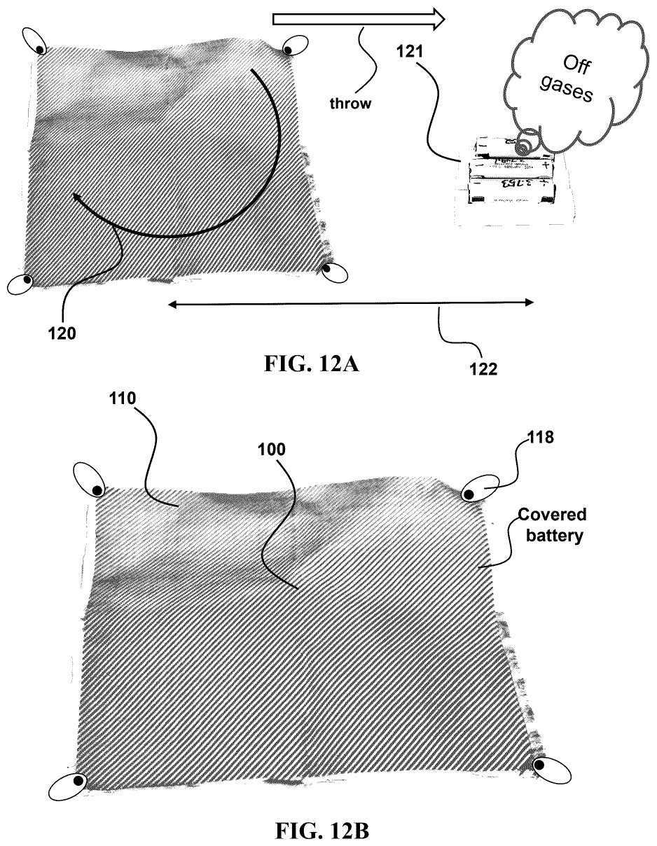

FIG. 12A illustrates the spinning/rotation motion 120 of the blanket toward batteries in thermal runway 121. Also illustrated is an aerodynamic parameter 122 corresponding to throwing distance. This throwing distance may be improved by at least 50% compared to a blanket that is not weighted. FIG. 12B is a partially transparent view showing the resting position of the blanket after throwing that covers the runaway batteries 121, thereby containing and retarding any flames by action of the fire retardant material and, upon release of fire suppressant material, suppressing and putting out the fire, thereby stopping the thermal runaway of batteries 100. The weighted material 118 has an additional functional benefit of reliably and intimately forcing contact of blanket over the batteries, and minimizing risk of air pockets that could prolong the runaway thermal state of the batteries.

The preferred method of using the blanket is to throw it; however, a first responder or resident may choose to place the blanket over a rechargeable battery. The blanket can be hand placed or pulled over the battery using a hook-and-line or attachable line or cable that can drag the blanket to the desired position over the rechargeable battery.

The blanket may also be used to protect equipment and structures near a battery and act as a fire barrier. This could include critical infrastructure such as communication systems, flammable gas lines, flammable fuel storage tanks, gas cylinders, chemical tanks, and electrical systems. In addition to placing the blankets on or over batteries, they can be placed on the equipment and structures. For example, the blankets can be mounted on a door that divides two spaces, one which contains batteries and the other being occupied space or which contains other hazards or infrastructure that if exposed to fire would also burn, incapacitate or disable critical systems. If people occupy the space, the fire protective barrier could delay a fire and thus give individuals time to escape or evacuate.

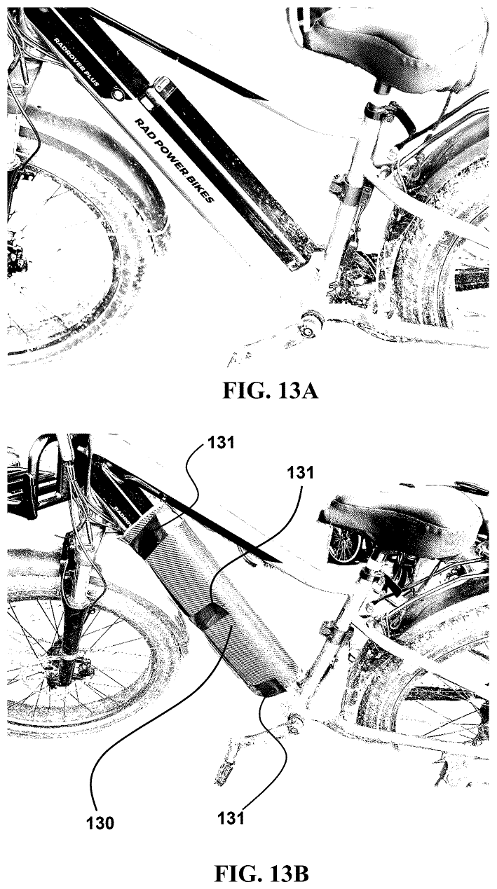

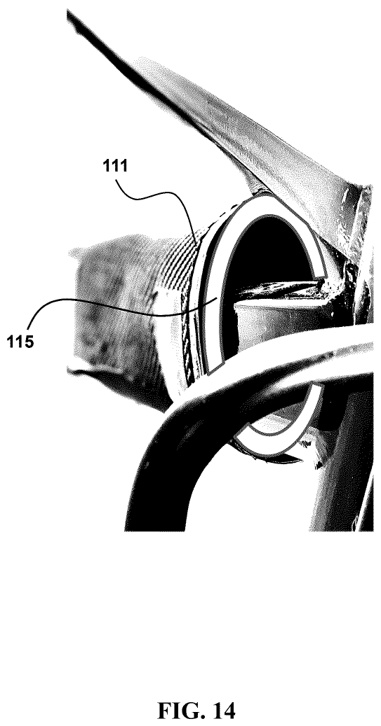

Another embodiment of the blanket is illustrated in FIGS. 13A, 13B and 14; namely a wrappable blanket 130 having fasteners 131 to tightly wrap the blanket 130 around the battery surface. In this manner, risk of a dangerous battery fire is reduced or avoided. This is particularly important for individuals who store their rechargeable battery operated personal transportation device in their home or apartment. This may include e-bikes, scooters, skateboards, one wheels and the like. Most homes are simply not equipped to contain or put out a battery fire, including a lithium-ion battery fire. Accordingly, it is beneficial to wrap the battery with any of the wrappable blankets described herein to avoid fires from faulty or damaged batteries.

FIG. 14 is a cut-away view of the blanket-wrapped battery of e-bike of FIG. 13B. The blanket as an outer layer of a fire retardant material, such as a fabric, and an inner pouch that contains a fire suppressant material.

Such wrappable blankets are further useful for storing, transport, packaging and/or disposal of batteries, including damaged or commercially-spent lithium ion batteries that may still carry charge.

The wrappable blankets provided herein are also characterized as being conformable. “Conformal” refers to the ability of the blankets to undergo a macroscopic shape change so as to adopt the curvature of the underlying to-be-wrapped battery, and associated battery support environment. The conformal contact is functionally characterized as the blanket maintaining intimate contact with the battery such that thermal runaway is suppressed and retarded.

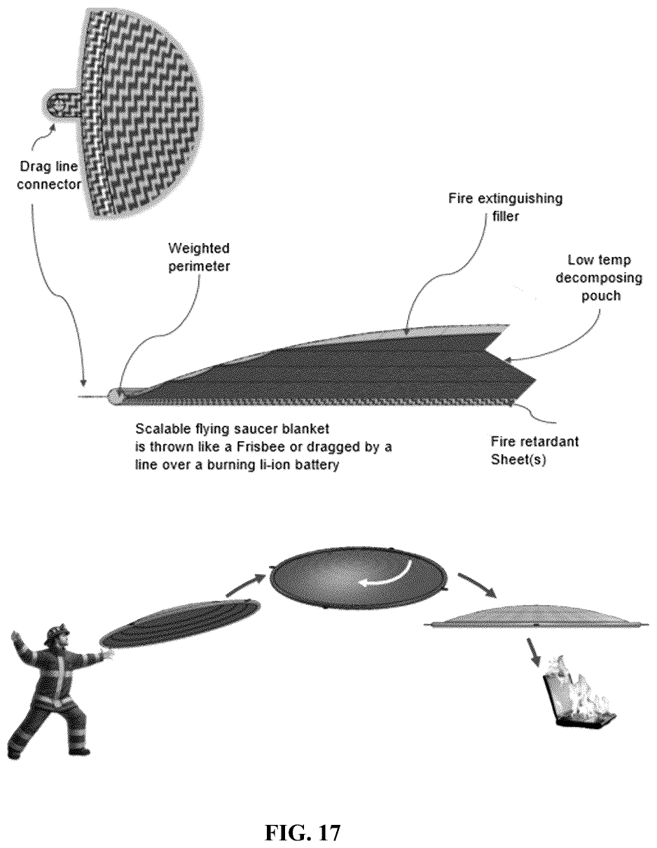

The blankets are further advantageous in that they are readily scaled to size depending on the application of interest and can be readily configured to have any desired geometric shape. For throwable embodiments (see, e.g., FIG. 17), the shape may be circular to effectively facilitate a Frisbee type throwing motion. For wrappable embodiments, including for an e-bike, the shape may be rectangular so that battery and frame to which the battery is integrated, can be wrapped in conformal contact. For automobile applications, the blanket can be sized and shaped to reliably contact the automobile rechargeable battery. For disposal or battery transport applications, the blanket can be shaped to contain the battery form factor itself.

### Example 2: Battery Blanket with Thermal Monitoring and Alarm

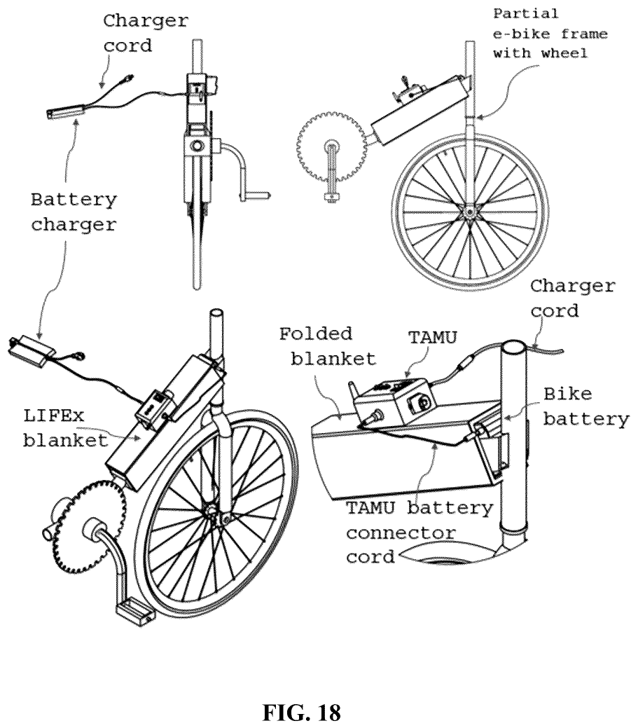

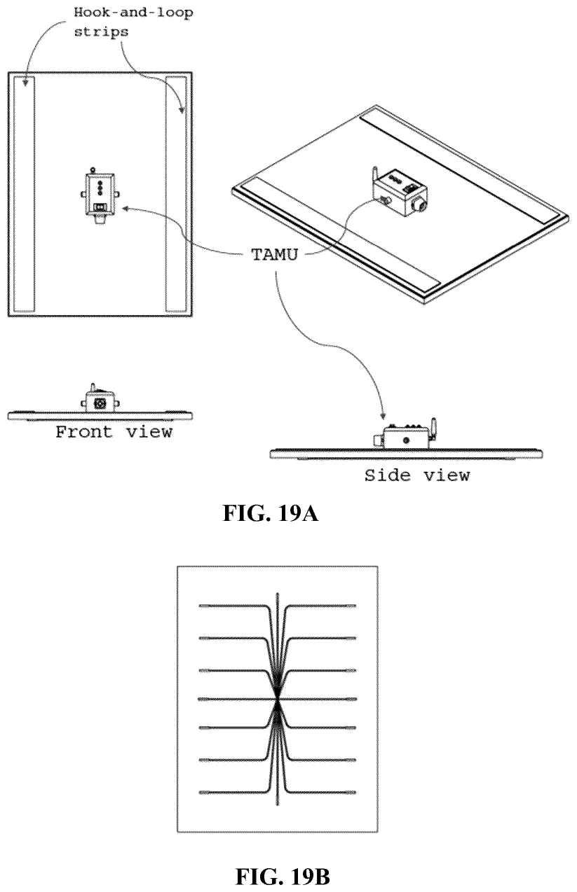

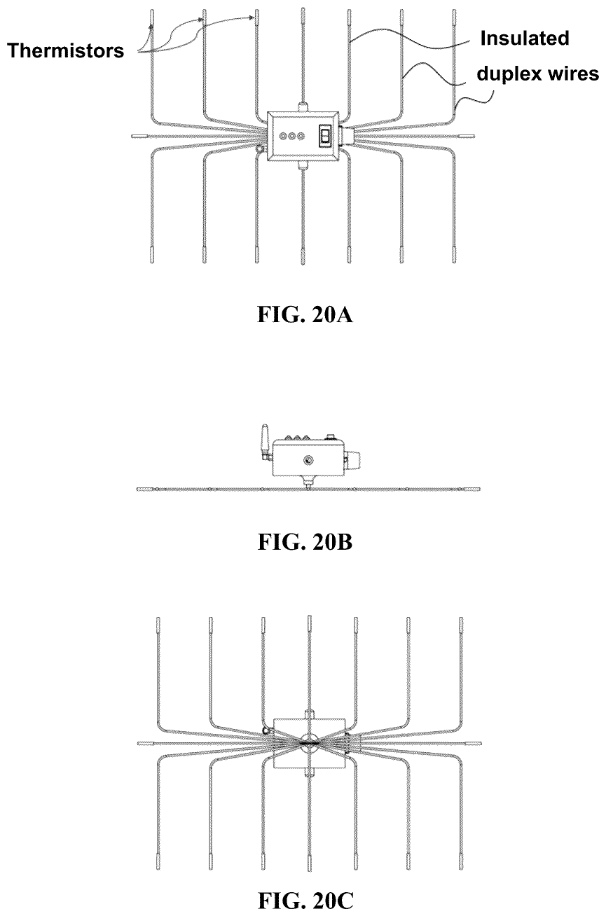

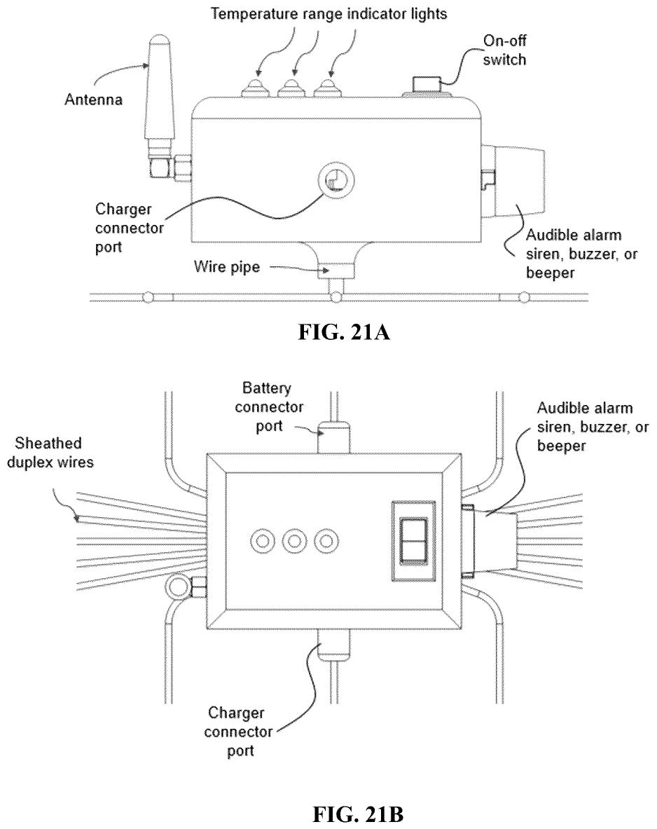

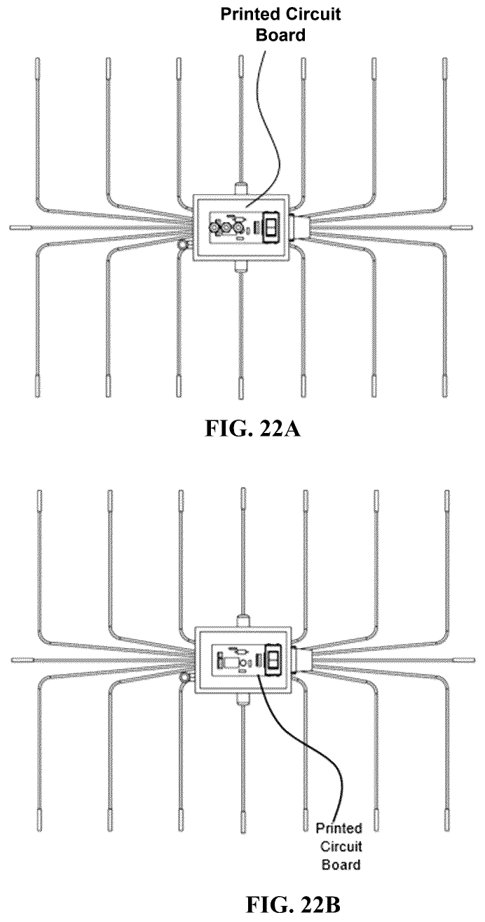

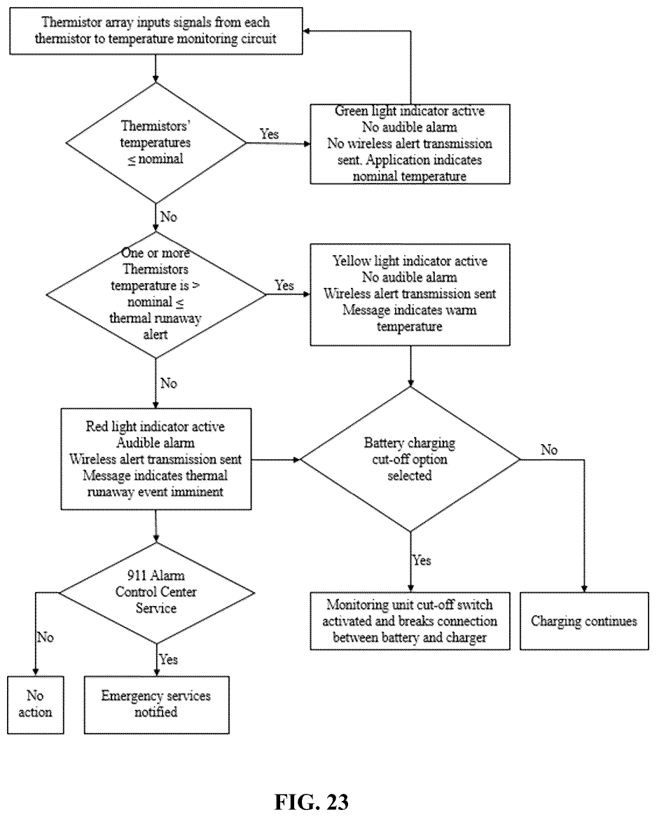

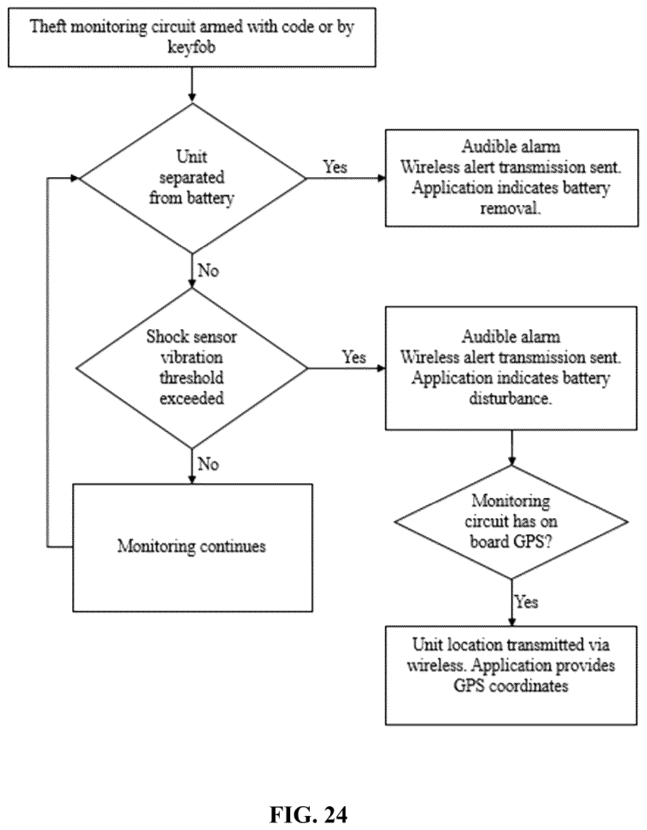

Referring to FIGS. 18-24, an optional component for any of the battery blankets described herein is a temperature sensor that can measure the temperature around the battery that is in proximity or covered by the blanket. The temperature may be a thermistor, including an array of thermistors that are supported by or integrated with the blanket. In an aspect, they may connect to an external facing surface of the blanket. The array of thermistors are preferably arranged to ensure at least a portion of the thermistors will be in close proximity to the battery. In this manner, an adverse temperature condition generated by a damaged or failing battery, can be automatically detected. The temperature sensor may be electronically connected to a warning system, such as a light and/or audio alarm.

In an example, a pouch is positioned on the outside of the blanket to house the alarm circuitry enclosure, such as an alarm box. An array of thermistors are wired to the alarm box that will trigger the alarm at one or more temperature values. For example, at normal temperatures, such as less than a selected low temperature, such as less than about 30° C., a light of the alarm may be steady green (indicating normal battery condition). At a middle temperature range, such as between about 30° C. and 100° C., the light of the alarm may be a slow blinking yellow (indicating a potential warm condition). At a high temperature range, such as above about 100° C., there may be flashing red along with a loud audible alarm (indicating a dangerous heat condition). Of course, the actual temperature cut-offs between states will depend on the battery type, operating conditions, and the like and can be appropriately selected to ensure there is time to take action, including evacuation and/or removal of the at-risk device to an area of lower concern (e.g., from inside to outside a building).

The alarm can be driven by a battery or wall-outlet. A thin fabric or plastic sleeve may hold the array of thermistors that will wrap around a battery. Hook-and-loop or straps can be used to wrap the battery. The blanket can cover the alarm sensor sleeve. Alternatively, the sensors can be connected to a flexible thermally conductive strip that can attach to a battery via an adhesive or magnetically. The sensors may be hard-wired connected to the alarm, or may wirelessly communicate with a communication receiver operably connected to the alarm.

Aspects of the electronic circuit optionally include one or more of: On-off switch; Power level indicator light; Temperature level indicator light(s); Alarm zone indicator (lets you know which thermistor(s) are hot); Alarm visual/audible siren; Wifi transmitter to smartphone or tablet (App for the LIFEx-TR) and/or cellular transmitter for smartphone or tablet (App for the LIFEx-TR)- useful for remote monitoring, can call the owner of an alert or even a 911 alert to notify responders; App can show current temperature range and which zone(s) are affected); Communicate with home-owners alarm system (if they have one).

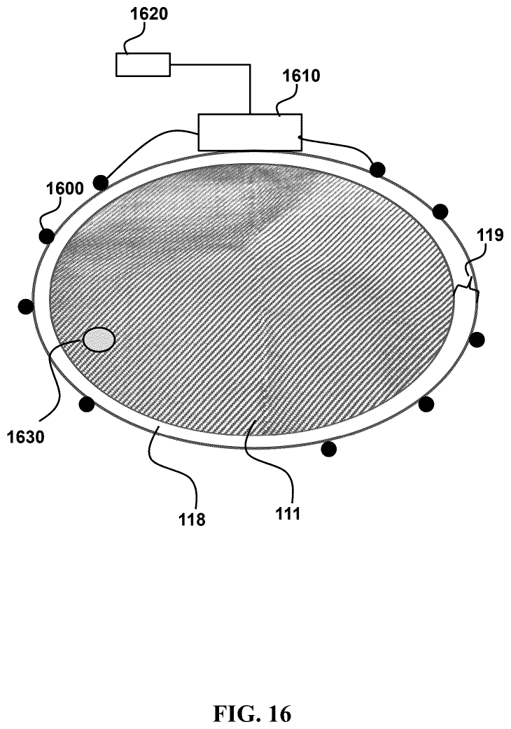

FIG. 16 schematically illustrates an array of temperature sensors 1600 (e.g., thermistors), alarm 1610 (illustrated as connected to blanket), electric cut-off 1620 (see, e.g., Example 3 below), and/or anti-theft component 1630.

### Example 3: Electric Cut-Off

Any of the devices described herein may further incorporate a battery charger cut-off (see, e.g., FIG. 16 cut-off 1620). This is useful to, as early as possible, to stop charging the battery, this may be incorporated with the temperature sensor embodiment, so that for a warm condition (greater than about 30° C.) the switch may be opened to prevent any further battery charging. For a hot temperature condition, the battery charger cutoff is activated.

The battery cutoff switch can splice into an existing charger cord between the charger and the battery (there are two wires in the charger cord). The electronic switch is integrated into an enclosure with wire splice connectors. There is an oxide inhibitor material to prevent corrosion and the electric connectors are coated with a rubber PVC coating. The cutoff switch holds its open state even if there is a power loss after it is triggered. Alternatively, the cut-off switch encloser has a female receptacle for the male end of the charging cord. There is a male end on the switch box that plugs into the battery. It couples the cord and battery.

The functional benefit of the cut-off 1620 is to reliably trigger a switch to an open state based on an input from the array of temperature sensors, thereby stopping charging. While a fire may or may not be prevented (depending on the extent of battery damage), the goal is to increase time available to take action before a fire event, thereby facilitating movement of persons and property to safety, including moving battery out of a building outside to an area that has less risk of catching and spreading the battery fire to a structure.

### Example 4: Anti-Theft

Particularly for readily removable and mobile expensive battery devices, including e-bikes, any of the blanket batteries may have further incorporated an anti-theft device 1630. The anti-theft may have a keypad or fob arming. After arming, any of a variety of states may trigger an alarm (including a signal to a remote owner), including: removal of the blanket, battery removal, movement of device (e.g., bike motion), wheel rotation vibration, or tilt of bike.

### Example 5: Two-Part Expanding Foam

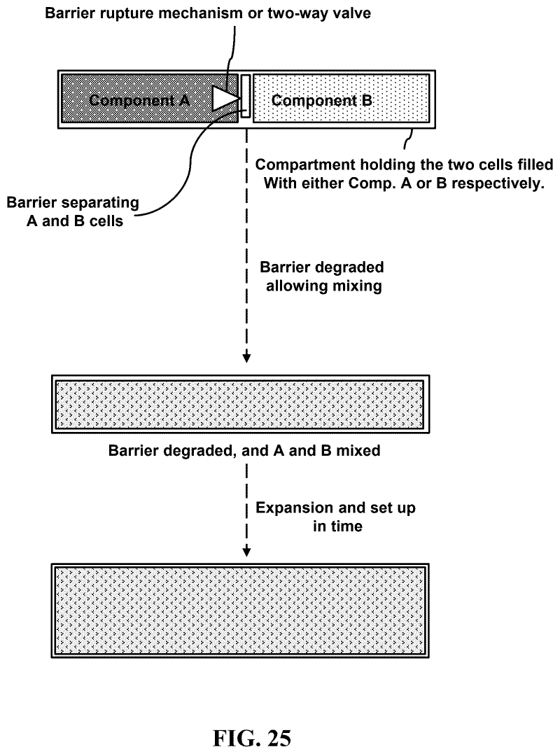

In one embodiment, two part expanding foam is used (FIG. 25), and that expanding foam may generally correspond to at least one SMART layer. The foam is made of two chemical components that after mixing cause a chemical reaction. The reaction results in gases and new compounds forming and foaming. These two-part foams expand rapidly, such as within about 2-5 minutes after mixing, and then generally sets within 5 to 30 minutes, depending on the foam model. The two fluid components, ‘A’ and ‘B’ are contained within cells inside of the SMART layer compartment and they are separated by a barrier, referred herein as a “degradable barrier” to reflect that the barrier can be controllably pierced, removed, or otherwise bypassed to provide mixing of the two components A and B. Accordingly, degradable barrier is intended to encompass aspects including: a mechanism such as a puncture device, a rupturable membrane barrier, a controllable passage(s) or pores, or the like, facilitates mixing of the two foam components A and B, a valve that is opened by turning or pressure applied. The valve is operably connected to both ‘A’ and ‘B’ cells allowing the fluid A and B to mix. Polyurethane is one example of a foam that can be used. The expansion ratio may be between about 2-8 times compared to the pre-expansion mixing volume. The use of 2-part foams is beneficial in that in a storage mode, the BAFMA is compact, with the 2-parts physically isolated from each other in separate compartments. Most foams set within 5-minutes to 30 minutes. The foam will conform to the shape of the SMART compartment. In another embodiment, the SMART compartment contains only one component ‘A’ and a through bulkhead type valve or opening such as a nipple allows the second component ‘B’ to be added by pouring it into the SMART compartment. The valve can be a one-way valve. Having component ‘A’ stored separately until activation of the BAFMA system greatly reduces storage space requirements. Accordingly, any of the devices or methods provided herein may further relate to a BAFMA having a storage configuration and a BAFMA having a deployed configuration, wherein in the storage configuration the two-part foam has not been mixed (e.g., low volume) and in the deployed configuration the two-part foam is mixed (e.g., high volume that is greater than the low volume, such as between about 2× to 8× greater volume).

### Example 6: Electromagnetic Spectrum Isolation

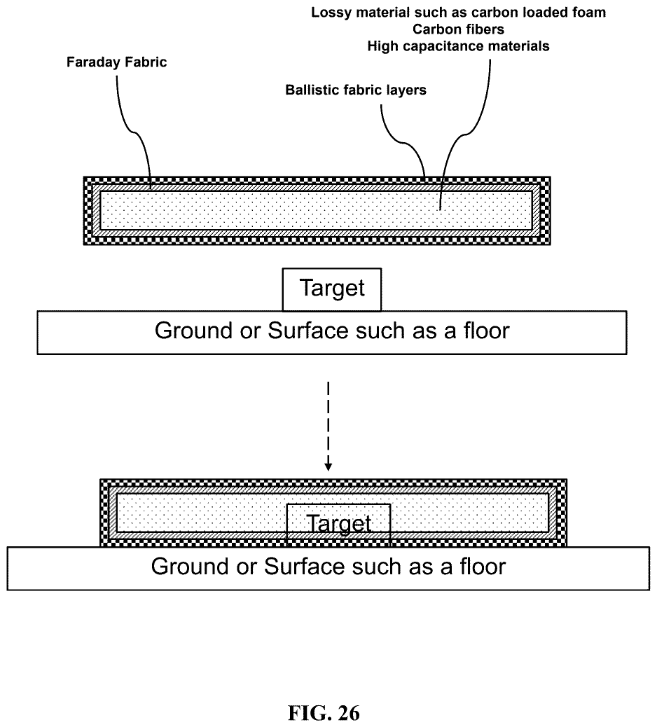

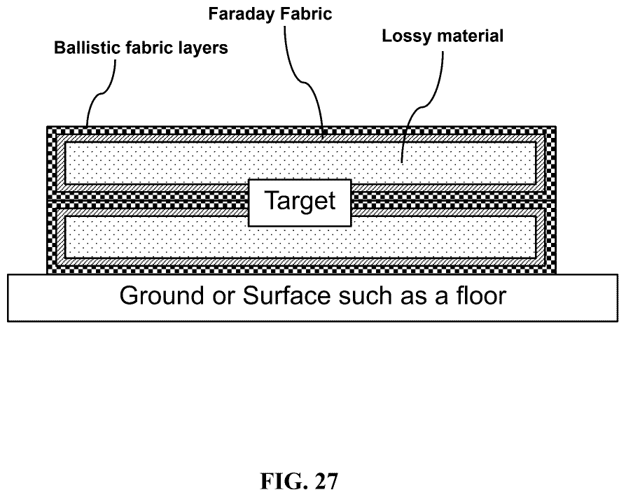

Referring to FIGS. 26-27, any of the BAFMA and blankets provided herein may have a layer to block electromagnetic signals to and/or from the device. Examples include a faraday fabric, a fluid body comprising a lossy material (e.g., electrically conductive filler), or a fluid body that behaves equivalently as an electrical network having resistance, capacitance and inductance properties which attenuate electromagnetic radiation. A fluid body in this context is a substance that takes the shape of any container. The fluid can be made of solid particles, a liquid, or a combination thereof. A fluid body can be a readily conformable absorbent foam, which entraps particles or liquids.

I claim:

1. A Blast and Fragment Mitigating Apparatus (BAFMA) to contain a hazardous device initiation comprising:
a top subassembly;
a bottom subassembly, wherein the top subassembly and bottom subassembly are operably connected to form an inner volume configured to contain the hazardous device;
wherein each of the top subassembly and the bottom subassembly independently comprise:
a bladder having a bladder volume;
a fluid body contained within the bladder volume;
a plurality of flexible and conformable layers that surround the bladder;
wherein upon hazardous device initiation of the hazardous device positioned in the inner volume, the bladder is configured to rupture and the fluid body and/or plurality of flexible and conformal layers are configured to provide one or more device safety parameters, the device safety parameters selected from the group consisting of:
a blast energy absorption;
ejected hazardous device fragment(s) deceleration;
fire resistance; and
thermal event suppression.

2. The BAFMA of claim 1, wherein at least one of the plurality of layers is selected from the group consisting of:
a ballistic fiber, including a ballistic aramid fiber fabric sheet;
a SMART layer selected from the group consisting of: rigid polyurethane, a vinyl closed cell foam, a polyvinylchloride foam, and a structural foam;
a flame retardant layer, optionally formed from any one or more materials selected from the group consisting of: aramid fibers; basalt fibers, fiberglass;
Nomex® meta-aramid, poly(meta-phenyleneisophthalamide); Carbon felt/graphite felt; Ballistic fabrics; Silicone coated fiberglass; Ceramic oxide fibers; and Ceramic impregnated fabrics.

3. The BAFMA of claim 2, wherein the SMART layer comprises a two-part expanding foam, the two-part expanding foam formed from:
a first chemical component positioned within a first cell;
a second chemical component positioned in a second cell;
a degradable barrier separating the first cell from the second cell;
wherein degradation of the degradable barrier mixes the first chemical component with the second chemical component and provide the two-part expanding foam that provides an increase in volume of the SMART layer compared to a SMART layer volume before mixing.

4. The BAFMA of claim 1, wherein the fluid body comprises suspended particles to form a dilatant fluid/slurry material configured to deflect, redirect and absorb a shock wave upon a hazardous device initiation.

5. The BAFMA of claim 1, further comprising in each of the top and bottom subassemblies:
a faraday fabric layer for electromagnetic communication attenuation with the hazardous device;
an electrical network forming an inner layer that surrounds the bladder, the electrical network configured to provide continuous broadband attenuation of electromagnetic radiation by absorption, reflection, and dispersion, including formed from a conductive and capacitive filler having a thickness selected for a user-desired attenuation level and frequency range, including between 1 kHz and 100 GHz; and/or
the fluid body comprising an electrically conductive filler having a defined conductance and capacitance to attenuate electromagnetic radiation by absorption, reflection, and dispersion to a user-desired attenuation level and frequency range including between 1 kHz and 100 GHz;
wherein connection of the top and bottom sub-assemblies fully encapsulates the inner volume and blocks an electromagnetic signal to or from the hazardous device positioned in the inner volume.

6. A method of attenuating a hazardous device initiation, the method comprising the steps of:
providing the BAFMA of claim 1;
positioning a fluid body in each of the bladder volumes;
placing the hazardous device in the inner volume formed by the top and bottom subassemblies;
operably connecting the top and bottom subassemblies;
thereby attenuating the hazardous device initiation, wherein the attenuation comprises one or more of: blast attenuation, fragment mitigation, fire suppression, fire retardation, and vapor neutralization.

7. The method of claim 6, further comprising the step of selecting one or more of the plurality of layers to control at least one containment parameter selected from the group consisting of:
a blast peak overpressure;
a blast shock impulse;
a fragmentation velocity;
a flame; and
a thermal runaway.

8. A fire extinguishing blanket comprising:
a layer comprising a fire retardant material having an inner surface and an outer surface separated by a thickness of the layer;
a pouch connected to the layer inner surface that defines a pouch volume;
a fire extinguishing material positioned in the pouch volume, the fire extinguishing material comprising a chemical to suppress a rechargeable battery fire, wherein the pouch is at least partially formed of a pouch material that degrades at a fire release temperature to release the fire extinguishing material;
at least one of:
a weighted material positioned in a perimeter region of the layer, the weighted material having a density greater than a layer density and fire extinguishing material density, wherein the weighted material is configured to improve an aerodynamic parameter and thereby provide the fire extinguishing blanket that is controllably throwable; and/or one or more fasteners connected to the fire retardant material outer surface and/or fire extinguishing material layer, wherein the fasteners are configured to provide a blanket open configuration and a blanket wrapped configuration sized to contain a rechargeable battery and thereby provide the fire extinguishing blanket that is wrappable.

9. The fire extinguishing blanket of claim 8, wherein the fire retardant material is selected from the group consisting of:
aramid fibers;
fiberglass;
Nomex® meta-aramid, poly(meta-phenyleneisophthalamide);
carbon felt or graphite felt;
a ballistic fabric;
silicone coated fiberglass;
ceramic oxide fibers; and
ceramic impregnated fabrics.

10. The fire extinguishing blanket of claim 8, wherein the fire extinguishing material is selected from the group consisting of:
sodium bicarbonate;
silicone;
monoammonium phosphate; and
ammonium sulfate.

11. The fire extinguishing blanket of claim 8, wherein the pouch comprises:
an outer wall formed of the fire retardant material; and
an inner wall formed from an inner sheet, including a cloth or plastic sheet;
wherein the pouch releases the fire extinguishing material at the fire release temperature that is below a melting point temperature of the fire retardant material.

12. The fire extinguishing blanket of claim 8, wherein the aerodynamic parameter is a throw distance that is 20 feet or greater.

13. The fire extinguishing blanket of claim 8, wherein the rechargeable battery is a lithium-ion battery, alkaline battery, nickel metal hydride battery, lead acid battery, lithium polymer battery, nickel-cadmium, lithium iron phosphate, or zinc carbide battery.

14. The fire extinguishing blanket of claim 8, wherein the rechargeable battery is mounted to a vehicle body, including a bicycle frame.

15. The fire extinguishing blanket of claim 8, further comprising a ballistic fabric layer adjacent to the fire retardant material layer.

16. A method of suppressing and retarding a rechargeable battery fire, the method comprising the steps of:
providing a the fire extinguishing blanket of claim 8; and
one of:
throwing the controllably throwable fire extinguishing blanket over the rechargeable battery fire; or
wrapping the wrappable fire extinguishing blanket over a rechargeable battery at risk of a rechargeable battery fire.

17. A blanket to contain a hazardous device initiation comprising:
a plurality of layers comprising:
a flexible and conformable outer ballistic layer configured to conform to a hazardous device shape, the flexible and conformable outer ballistic layer formed from a material selected to have a tensile strength, an ignition temperature, and melting point to absorb and withstand device initiation without failure; and
a flame retardant inner layer to retard or suppress a flame;
wherein upon device initiation the plurality of layers are configured to:
absorb a blast energy;
stop ejected fragments;
resist a fire;
retard a fire; and/or
suppress a thermal event.

18. The blanket of claim 17, further comprising:
an array of temperature sensors connected to at least one surface of the plurality of surfaces, wherein the array of temperature sensors are configured to measure a temperature of the hazardous device that comprises a battery;
an alarm operably connected to the array of temperature sensors to generate a warning of an adverse battery temperature event indicative of an initiation risk corresponding to a battery thermal runaway; and
optionally, a rechargeable battery cut-off having an actuatable switch configured to open upon the adverse battery temperature event.

19. The blanket of claim 17, further comprising in the plurality layers:
a faraday fabric layer for electromagnetic communication attenuation with the hazardous device; and/or
a fluid body contained in a bladder, wherein the fluid body comprises an electrically conductive filler having a defined conductance and capacitance to attenuate electromagnetic radiation by absorption, reflection, and dispersion.

20. A method of attenuating an electromagnetic signal to prevent a hazardous device from receiving an electromagnetic signal to initiate the device, the method comprising the steps of:
providing the blanket of claim 19; and
one of:
throwing the blanket over a hazardous device;
wrapping the wrappable blanket over a hazardous device; or
remotely placing the hazardous device atop the blanket and entirely covering the hazardous device with the blanket.
